(19) United States
(12) Patent Application Publication
(10) Pub. No.: US 2017/0076964 A1
(43) Pub. Date: Mar. 16, 2017

(54) SUBSTRATE PROCESSING APPARATUS

(71) Applicant: HITACHI KOKUSAI ELECTRIC INC., Tokyo (JP)

(72) Inventor: Motoshi SAWADA, Toyama-shi (JP)

(73) Assignee: HITACHI KOKUSAI ELECTRIC INC., Tokyo (JP)

(21) Appl. No.: 15/262,161

(22) Filed: Sep. 12, 2016

(30) Foreign Application Priority Data
Sep. 14, 2015 (JP) 2015-180483

(51) Int. Cl. H01L 21/67; H01J 37/32

(52) U.S. Cl. CPC H01L 21/67109; H01J 37/32009; H01J 37/32724; H01L 21/67017; H01L 21/67248; H01L 21/67167; H01J 2237/334

(57) ABSTRACT

A substrate processing apparatus includes process chambers configured to process substrates, process modules each including juxtaposed process chambers configured to process substrates, heat medium flow paths respectively installed in the process modules, and temperature adjustment parts individually installed in a corresponding relationship with the process modules and configured to allow a heat medium to flow through the flow paths installed in the process modules. Each of the flow paths includes: upstream and downstream flow path portions positioned at an upstream side and a downstream side of each of the process modules, a penetration flow path portion connected to the upstream flow path portion and configured to extend between the juxtaposed process chambers of each of the process modules, and an outer periphery flow path portion connected to the downstream flow path portion and configured to extend along an outer periphery of each of the process modules.

### CROSS-REFERENCE TO RELATED APPLICATION(S)

This application is based upon and claims the benefit of priority from Japanese Patent Application No. 2015-180483, filed on Sep. 14, 2015, the entire contents of which are incorporated herein by reference.

### TECHNICAL FIELD

The present disclosure relates to a substrate processing apparatus.

### BACKGROUND

As one form of a substrate processing apparatus used in a semiconductor device manufacturing process, there is available, for example, a substrate processing apparatus in which a plurality of (e.g., four) process modules each having a process chamber (reactor) is radially disposed around a transfer chamber. In the substrate processing apparatus of this configuration, the processing of substrates such as wafers or the like may be simultaneously performed in the respective process modules. However, there is a need to equalize the process conditions in the respective process modules. Thus, flow paths are formed in the respective process modules and temperature adjustment parts are connected to the respective flow paths. The temperature adjustment parts allow a heat medium to flow and circulate through the respective flow paths, thereby maintaining the process chambers of the respective process modules at a predetermined temperature (e.g., at about 50 degrees C.).

In the substrate processing apparatus having the aforementioned configuration, there may be a case where the same processing is performed in the respective process modules in order to increase the productivity. In this case, from the viewpoint of a yield rate, the substrates processed in the respective process modules need to be kept at a consistent quality. Thus, the processing condition in the respective process modules needs to be maintained at a condition under which a specified quality is obtained. The term “processing condition” used herein refers to, for example, a temperature condition.

### SUMMARY

The present disclosure provides some embodiments of a technique capable of, even when there is provided a plurality of process modules, keeping the substrate processing condition of the respective process modules at a condition under which a specified quality is obtained.

According to one embodiment of the present disclosure, there is provided a technique, including: a plurality of process modules configured to process substrates; a plurality of heat medium flow paths respectively installed in the process modules; a plurality of sensors configured to detect a state of a heat medium flowing through the flow paths; and a plurality of temperature adjustment parts individually installed in a corresponding relationship with the process modules, configured to allow the heat medium, which adjusts a temperature of the process modules, to flow through the flow paths installed in the process modules, and configured to control the heat medium flowing through the flow paths in a predetermined state based on detection results obtained by the sensors.

### BRIEF DESCRIPTION OF THE DRAWINGS

FIG. 1 is an explanatory view illustrating a schematic configuration example of a substrate processing apparatus according to a first embodiment of the present disclosure.

FIG. 2 is an explanatory view schematically illustrating a schematic configuration example of a process chamber of the substrate processing apparatus according to the first embodiment of the present disclosure.

FIG. 3A is an explanatory plane view schematically illustrating one example of a winding form of a pipe in the substrate processing apparatus according to the first embodiment of the present disclosure, FIG. 3B is a sectional view taken along line A-A in FIG. 1 or 3A, and FIG. 3C is a view of arrow B in FIG. 3B.

FIG. 4 is a flowchart illustrating an overview of a substrate processing process according to a first embodiment of the present disclosure.

FIG. 5 is a flowchart illustrating the details of a film forming process in the substrate processing process illustrated in FIG. 4.

FIG. 6 is an explanatory view schematically illustrating one example of a substrate processing apparatus according to a comparative example of the present disclosure.

FIG. 7 is an explanatory view illustrating a schematic configuration example of a substrate processing apparatus according to a second embodiment of the present disclosure.

FIG. 8 is an explanatory view illustrating a schematic configuration example of a substrate processing apparatus according to a third embodiment of the present disclosure.

### DETAILED DESCRIPTION

Embodiments of the present disclosure will now be described in detail with reference to the drawings.

### First Embodiment of the Present Disclosure

First, descriptions will be made on a first embodiment of the present disclosure.

### (1) Configuration of Substrate Processing Apparatus

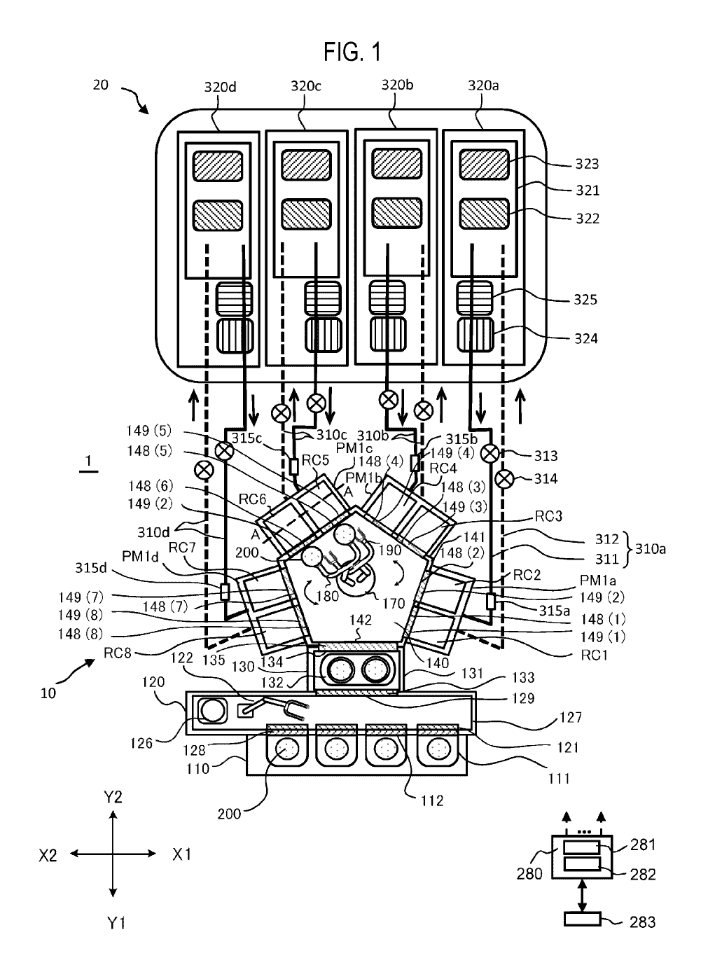

FIG. 1 is an explanatory view illustrating a schematic configuration example of a substrate processing apparatus according to a first embodiment of the present disclosure. When generally divided, the substrate processing apparatus 1 of the illustrated example include a main body part 10 of the substrate processing apparatus, a temperature adjustment system part 20 and a controller 280.

### <Configuration of Main Body Part>

The main body part 10 of the substrate processing apparatus 1 is of a so-called cluster type in which a plurality of process chambers is provided around a substrate transfer chamber. The cluster type main body part 10 of the substrate processing apparatus 1 is configured to process wafers 200 as substrates and is mainly configured by an IO stage 110, an atmosphere transfer chamber 120, a load lock chamber 130, a vacuum transfer chamber 140 and process modules PM1a to PM1d. The respective components will now be described in detail. In describing FIG. 1, it will be assumed that the X1 direction is right, the X2 direction is left, the Y1 direction is front, and Y2 direction is rear.

### (Atmosphere Transfer Chamber and IO Stage)

At the front side of the substrate processing apparatus 1, there is installed the IO stage (load port) 110. A plurality of front opening unified pods (FOUPs) (hereinafter referred to as “pods”) configured to store a plurality of wafers is mounted on the IO stage 110. The pods 111 are used as carriers which carry wafers 200 such as silicon (Si) substrates or the like. Unprocessed wafers 200 or processed wafers 200 are stored in a horizontal posture within the pods 111.

A cap 112 is installed in the pod 111 and is opened or closed by a pod opener 121 which will be described later. The pod opener 121 opens or closes the cap 112 of the pod 111 mounted on the IO stage 110 and opens or closes a substrate loading/unloading opening, thereby making it possible to load and unload the wafers 200 with respect to the pod 111. The pod 111 is supplied to or discharged from the IO stage 110 by an automated material handling system (AMHS) not shown.

The IO stage 110 is disposed adjacent to the atmosphere transfer chamber 120. The atmosphere transfer chamber 120. The load lock chamber 130, which will be described later, is connected to the opposite side of the atmosphere transfer chamber 120 from the IO stage 110.

An atmosphere transfer robot 122 which transfers the wafers 200 is installed within the atmosphere transfer chamber 120. The atmosphere transfer robot 122 is configured to be moved up and down by an elevator (not shown) installed in the atmosphere transfer chamber 120 and is configured to be reciprocated in a left-right direction by a linear actuator (not shown).

At the left side of the atmosphere transfer chamber 120, there is installed a device (hereinafter also referred to as “pre-aligner”) 126 which aligns notches or orientation flats formed in the wafers 200. In the upper portion of the atmosphere transfer chamber 120, there is installed a clean unit (not shown) which supplies a clean air.

At the front side of a housing 127 of the atmosphere transfer chamber 120, there are installed a substrate loading/unloading gate 128 for loading and unloading the wafers 200 with respect to the atmosphere transfer chamber 120 and a pod opener 121. The IO stage (load port) 110 is installed at the opposite side of the substrate loading/unloading gate 128 from the pod opener 121, namely at the outer side of the housing 127.

The pod opener 121 opens or closes the cap 112 of the pod 111 mounted on the IO stage 110 and opens or closes a substrate loading/unloading opening, thereby making it possible to load and unload the wafers 200 with respect to the pod 111. The pod 111 is supplied to or discharged from the IO stage 110 by an in-process transfer device not shown.

At the rear side of the housing 127 of the atmosphere transfer chamber 120, there is installed a substrate loading/unloading gate 129 for loading and unloading the wafers 200 with respect to the load lock chamber 130. The substrate loading/unloading gate 129 is opened or closed by a gate valve 133 which will be described later, thereby making it possible to load or unload the wafers 200.

### (Load Lock Chamber)

The load lock chamber 130 is disposed adjacent to the atmosphere transfer chamber 120. As will be described later, the vacuum transfer chamber 140 is disposed on the opposite surface of a housing 131 of the load lock chamber 130 from the atmosphere transfer chamber 120. The internal pressure of the housing 131 of the load lock chamber 130 varies in conformity with the pressure of the atmosphere transfer chamber 120 and the pressure of the vacuum transfer chamber 140. Thus, the load lock chamber 130 is configured to have a structure capable of withstanding a negative pressure.

A substrate loading/unloading gate 134 is formed at the side of the housing 131 that adjoins the vacuum transfer chamber 140. The substrate loading/unloading gate 134 is opened or closed by a gate valve 135, thereby making it possible to load or unload the wafers 200.

A substrate mounting stand 132 having at least two substrate mounting surfaces for mounting the wafers 200 is installed within the load lock chamber 130. The distance between the substrate mounting surfaces is set depending on the distance between end effectors of arms of a robot 170 which will be described later.

### (Vacuum Transfer Chamber)

The main body part 10 of the substrate processing apparatus 1 includes a vacuum transfer chamber (transfer module) 140 as a transfer chamber serving as a transfer space in which the wafers 200 are transferred under a negative pressure. A housing 141 that constitutes the vacuum transfer chamber 140 is formed in a pentagonal shape in a plane view. The load lock chamber 130 and the process modules PM1a to PM1d for processing the wafers 200 are connected to the respective sides of the pentagonal housing 141. In the substantially central region of the vacuum transfer chamber 140, there is installed a robot 170 as a transfer robot which transfers the wafers 200 under a negative pressure.

A substrate loading/unloading gate 142 is located in the sidewall of the housing 141 that adjoins the load lock chamber 130. The substrate loading/unloading gate 142 is opened or closed by a gate valve 135, thereby making it possible to load or unload the wafers 200.

The vacuum transfer robot 170 installed within the vacuum transfer chamber 140 is configured to be moved up and down by an elevator while maintaining the air-tightness of the vacuum transfer chamber 140. Two arms 180 and 190 of the robot 170 are configured so that they can move up and down.

A heat transfer gas supply hole (not shown) for supplying a heat transfer gas into the housing 141 is formed in the ceiling of the housing 141. A heat transfer gas supply pipe (not shown) is connected to the heat transfer gas supply hole. A heat transfer gas source, a mass flow controller and a valve (all of which are not shown) are installed in the heat transfer gas supply pipe sequentially from the upstream side thereof, thereby controlling the supply amount of the heat transfer gas supplied into the housing 141. A gas which does not affect the films formed on the wafers 200 and which has high heat conductivity is used as the heat transfer gas. For example, a helium (He) gas, a nitrogen (H₂) gas or a hydrogen (H₂) gas is used as the heat transfer gas. A heat transfer gas supply part of the vacuum transfer chamber 140 is mainly configured by the heat transfer gas supply pipe, the mass flow controller and the valve. The heat transfer gas supply part may further include an inert gas source and a gas supply hole.

An exhaust hole (not shown) for exhausting the internal atmosphere of the housing 141 is formed in the bottom wall of the housing 141. An exhaust pipe (not shown) is connected to the exhaust hole. An auto pressure controller (APC), which is a pressure controller, and a pump (all of which are not shown) are installed in the exhaust pipe sequentially from the upstream side. A gas exhaust part of the vacuum transfer chamber 140 is mainly configured by the exhaust pipe, and the APC. The gas exhaust pipe may further include the pump and exhaust hole.

The atmosphere of the vacuum transfer chamber 140 is controlled by the cooperation of the gas supply part and the gas exhaust part. For example, the internal pressure of the housing 141 is controlled by the cooperation of the gas supply part and the gas exhaust part.

In some of five sidewalls of the housing 141, on which the load lock chamber 130 is not installed, a plurality of (e.g., four) process modules PM1a to PM1d is disposed so that the process modules PM1a to PM1d are radially positioned around the vacuum transfer chamber 140. The respective process modules PM1a to PM1d are configured to perform a specific process with respect to the wafers. As will be described later in detail, examples of the specific process may include various kinds of substrate processing processes such as a process of forming thin films on the wafers, a process of oxidizing, nitriding or carbonizing the surfaces of the wafers, a process of forming films of silicide or metal, a process of etching the surfaces of the wafers, a reflow process and the like.

Process chambers (reactors) RC1 to RC8 as chambers for performing processes with respect to the wafers are installed in the respective process modules PM1a to PM1d. A plurality of (e.g., two) process chambers RC1 to RC8 are installed in each of the process modules PM1a to PM1d. Specifically, the process chambers RC1 and RC2 are installed in the process module PM1a. The process chambers RC3 and RC4 are installed in the process module PM1b. The process chambers RC5 and RC6 are installed in the process module PM1c. The process chambers RC7 and RC8 are installed in the process module PM1d.

Partition walls are installed between the respective process chambers RC1 to RC8 of the respective process modules PM1a to PM1d so that the atmospheres of the below-described process spaces 201 are not mixed with each other. The process chambers RC1 to RC8 are configured so that they have independent atmospheres.

The configuration of the process chambers RC1 to RC8 of the respective process modules PM1a to PM1d will be described later.

Substrate loading/unloading gates 148 are formed in some of five sidewalls of the housing 141, which face the respective process chambers RC1 to RC8. Specifically, a substrate loading/unloading gate 148(1) is formed in the sidewall which faces the process chamber RC1. A substrate loading/unloading gate 148(2) is formed in the sidewall which faces the process chamber RC2. A substrate loading/unloading gate 148(3) is formed in the sidewall which faces the process chamber RC3. A substrate loading/unloading gate 148(4) is formed in the sidewall which faces the process chamber RC4. A substrate loading/unloading gate 148(5) is formed in the sidewall which faces the process chamber RC5. A substrate loading/unloading gate 148(6) is formed in the sidewall which faces the process chamber RC6. A substrate loading/unloading gate 148(7) is formed in the sidewall which faces the process chamber RC7. A substrate loading/unloading gate 148(8) is formed in the sidewall which faces the process chamber RC8.

The respective substrate loading/unloading gates 148 are opened or closed by gate valves 149, thereby making it possible to load or unload the wafers 200. The gate valves 149 are installed in a corresponding relationship with the process chambers RC1 to RC8. Specifically, a gate valve 149(1) is installed between the vacuum transfer chamber 140 and the process chamber RC1. A gate valve 149(2) is installed between the vacuum transfer chamber 140 and the process chamber RC2. A gate valve 149(3) is installed between the vacuum transfer chamber 140 and the process chamber RC3. A gate valve 149(4) is installed between the vacuum transfer chamber 140 and the process chamber RC4. A gate valve 149(5) is installed between the vacuum transfer chamber 140 and the process chamber RC5. A gate valve 149(6) is installed between the vacuum transfer chamber 140 and the process chamber RC6. A gate valve 149(7) is installed between the vacuum transfer chamber 140 and the process chamber RC7. A gate valve 149(8) is installed between the vacuum transfer chamber 140 and the process chamber RC8.

When loading or unloading the wafers 200 between the process chambers RC1 to RC8 and the vacuum transfer chamber 140, the gate valves 149 are kept in an open state. The loading or unloading of the wafers 200 is performed by allowing the arms 180 and 190 of the vacuum transfer robot 170 to enter the process chambers RC1 to RC8 through the gate valves 149.

### <Configuration of Temperature Adjustment System Part>

The temperature adjustment system part 20 is configured to adjust the temperature of the respective process modules PM1a to PM1d so that the process condition in the respective process modules PM1a to PM1d is kept within a predetermined range. Specifically, a heat medium is allowed to flow and circulate through pipes 310a to 310d which are heat medium flow paths wound around the respective process modules PM1a to PM1d, thereby keeping the process chambers of the respective process modules PM1a to PM1d at a predetermined temperature (e.g., at about 50 degrees C.).

The heat medium flowing through the pipes 310a to 310d is a fluid which is used to move heat between the temperature adjustment system part 20 and the respective process modules PM1a to PM1d in order to heat or cool the respective process modules PM1a to PM1d and control the respective process modules PM1a to PM1d at a target temperature. As the heat medium, it may be possible to use, for example, a fluorine-based heat medium such as Galden (registered trademark) or the like. This is because the fluorine-based heat medium is nonflammable and is usable over a wide temperature range from a low temperature to a high temperature and because the fluorine-based heat medium is superior in electrical insulating property. However, the heat medium need not necessarily be the fluorine-based heat medium. The heat medium may be, for example, a liquid heat medium such as water or the like, or a gaseous heat medium such as an inert gas or the like, as long as the heat medium is a fluid which can serve as a heat medium.

There may be a need to perform periodical maintenance with respect to the respective process modules PM1a to PM1d. When performing the maintenance, the supply of the heat medium to the process modules PM1a to PM1d as maintenance targets is stopped. In this case, if the supply of the heat medium to all the process modules PM1a to PM1d is stopped even when the maintenance target is, for example, one of the process modules PM1a to PM1d, the operation efficiency of the respective process modules PM1a to PM1d may be significantly reduced. Furthermore, for example, even when the supply of the heat medium is stopped with respect to only the maintenance target, if the temperature adjustment system part 20 collectively manages the heat medium supplied to the respective process modules PM1a to PM1d, a change in heat balance within the temperature adjustment system part 20 may be generated in response to the stop of supply of the heat medium or the resumption of supply of the heat medium. Thus, the temperature of the heat medium supplied to the process modules PM1a to PM1d, which are not the maintenance targets, may fluctuate. For that reason, there is a need to postpone the start of a process in the respective process modules PM1a to PM1d until the fluctuation of the temperature of the heat medium is stabilized. As a result, the operation efficiency of the respective process modules PM1a to PM1d may be reduced.

Accordingly, the temperature adjustment system part 20 according to the present embodiment includes a plurality of temperature adjustment parts 320a to 320d independently installed in a corresponding relationship with the respective process modules PM1a to PM1d. By employing this configuration, the temperature adjustment system part 20 makes it possible to realize maintenance on the unit of the process modules PM1a to PM1d and to suppress reduction of the operation efficiency of the respective process modules PM1a to PM1d.

### (Temperature Adjustment Part)

The respective temperature adjustment parts 320a to 320d constituting the temperature adjustment system part 20 are configured to allow the heat medium, which adjusts the temperature of the process modules PM1a to PM1d, to flow through the pipes 310a to 310d and are configured to control the state of the heat medium flowing through the pipes 310a to 310d. Thus, as will be described later, the respective temperature adjustment parts 320a to 320d have the same configuration.

Each of the temperature adjustment parts 320a to 320d includes a circulation tank 321 which is a container for retaining the heat medium. A heating unit 322 for heating the heat medium and a cooling unit 323 for cooling the heat medium are installed in the circulation tank 321. Due to the installation of the heating unit 322 and the cooling unit 323, each of the temperature adjustment parts 320a to 320d has a function of controlling the temperature of the heat medium. The heating unit 322 and the cooling unit 323 may be configured through the use of a well-known art. Detailed descriptions thereof will be omitted herein.

Furthermore, an upstream pipe portion 311 as an upstream flow path portion positioned at the upstream side of the process modules PM1a to PM1d in order to supply the heat medium to the corresponding process modules PM1a to PM1d and a downstream pipe portion 312 as a downstream flow path portion positioned at the downstream side of the process modules PM1a to PM1d in order to recover the heat medium circulated through the process modules PM1a to PM1d are connected to the circulation tank 321. In other words, each of the pipes 310a to 310d corresponding to each of the process modules PM1a to PM1d includes an upstream pipe portion 311 (see the solid line in the drawings) and a downstream pipe portion 312 (see the broken line in the drawings). A pump 324 that generates drive power (kinetic energy) for allowing the heat medium to flow through the pipe and a flow rate control part 325 that controls the flow rate of the heat medium flowing through the pipe are installed in the upstream pipe portion 311. Due to the installation of the pump 324 and the flow rate control part 325, each of the temperature adjustment parts 320a to 320d has a function of controlling at least one of the pressure and the flow rate of the heat medium. The pump 324 and the flow rate control part 325 may be configured through the use of a well-known art. Detailed descriptions thereof will be omitted herein.

The respective temperature adjustment parts 320a to 320d configured as above are spaced apart from the respective process modules PM1a to PM1d and are concentrated and collectively installed in one place. That is to say, the temperature adjustment system part 20 including the respective temperature adjustment parts 320a to 320d is concentrated and installed in a place, for example, a separate floor within a factory, which is spaced apart from the main body part 10 of the substrate processing apparatus 1 including the respective process modules PM1a to PM1d. This is because the main body part 10 and the temperature adjustment system part 20 of the substrate processing apparatus 1 differ in the necessary installation environment (the cleanliness within a clean room, etc.) and because the collective installation of the respective temperature adjustment parts 320a to 320d of the temperature adjustment system part 20 makes it easy to manage the heat medium or the like.

### (Pipe)

As described above, each of the pipes 310a to 310d which interconnect the process modules PM1a to PM1d and the temperature adjustment parts 320a to 320d corresponding thereto, include the upstream pipe portion 311 positioned at the upstream side of each of the process modules PM1a to PM1d and the downstream pipe portion 312 positioned at the downstream side of each of the process modules PM1a to PM1d. The pipe portion existing between the upstream pipe portion 311 and the downstream pipe portion 312 is configured to be wound around each of the process modules PMla to PM1d. A specific form of the winding of the pipe portion around each of the process modules PM1a to PM1d will be described later in detail.

Valves 313 and 314 for opening or closing the flow path of the heat medium formed inside the pipe are installed in the upstream pipe portion 311 and the downstream pipe portion 312. Furthermore, sensors 315a to 315d for detecting the state of the heat medium flowing through the pipe are installed in the upstream pipe portions 311 in a corresponding relationship with the respective process modules PM1a to PM1d. Examples of the state of the heat medium may include the pressure of the heat medium, the flow rate of the heat medium, the temperature of the heat medium and appropriate combinations thereof. The sensors 315a to 315d for detecting the state of the heat medium may be configured through the use of a well-known art. Detailed descriptions thereof will be omitted herein.

The respective process modules PM1a to PM1d are disposed so as to be radially located around the vacuum transfer chamber 140. On the other hand, the respective temperature adjustment parts 320a to 320d are spaced apart from the respective process modules PM1a to PM1d and are collectively installed. Thus, the pipe lengths of the pipes 310a to 310d that interconnect the respective process modules PM1a to PM1d and the respective temperature adjustment parts 320a to 320d are differently set depending on the corresponding process modules PM1a to PM1d. Specifically, for example, the pipe 310a for interconnecting the process module PM1a and the corresponding temperature adjustment part 320a and the pipe 310b for interconnecting the process module PM1b and the corresponding temperature adjustment part 320b differ in length from each other.

However, even if the pipe lengths of the pipes 310a to 310d vary depending on the respective process modules PM1a to PM1d, the pipe lengths of the respective pipes 310a to 310d from the installation positions of the respective sensors 315a to 315d to the respective process modules PM1a to PM1d are set so that the loss amount of the state of the heat medium flowing through the pipes 310a to 310d falls within a predetermined range. This makes it possible to suppress a change in the state of the heat medium, which may be generated until the heat medium whose state is detected by each of the sensors 315a to 315d reaches each of the process modules PM1a to PM1d. Specifically, it is possible to enable the loss amount such as the pressure reduction, the flow rate reduction or the temperature reduction of the heat medium to fall within a predetermined range.

Furthermore, the pipe lengths of the respective pipes 310a to 310d from the installation positions of the respective sensors 315a to 315d to the respective process modules PM1a to PM1d are set to become uniform in the respective pipes 310a to 310d. Thus, even if a change in the state of the heat medium is generated until the heat medium whose state is detected by each of the sensors 315a to 315d reaches each of the process modules PM1a to PM1d, it is possible to restrain the change in the state from varying depending on the respective process modules PM1a to PM1d.

### <Configuration of Controller>

The controller 280 serves as a control part (control means) that controls the processing operations of the main body part 10 and the temperature adjustment system part 20 of the substrate processing apparatus 1. Thus, the controller 280 includes at least an operation part 281 formed of a combination of a central processing unit (CPU), a random access memory (RAM) and the like, and a memory part 282 formed of a flash memory, a hard disk drive (HDD) or the like. In the controller 280 of this configuration, the operation part 281 reads various kinds of programs or recipes from the memory part 282 and executes the programs or recipes in response to the instructions of a host controller or a user. According to the content of the programs thus read, the operation part 281 controls the processing operation of the main body part 10 or the temperature adjustment system part 20.

Furthermore, it is conceivable that the controller 280 is configured by a dedicated computer device. However, the present disclosure is not limited thereto. The controller 280 may be configured by a general-purpose computer device. For example, the controller 280 according to the present embodiment may be configured by preparing an external memory device 283 (e.g., a magnetic tape, a magnetic disc such as a flexible disc, a hard disc or the like, an optical disc such as a CD, a DVD or the like, a magneto-optical disc such as an MO or the like, and a semiconductor memory such as a USB memory, a memory card or the like) and installing the program in a general-purpose computer device through the use of the external memory device 283. Furthermore, the means for supplying the program to the computer device is not limited to a case where the program is supplied via the external memory device 283. For example, the program may be supplied through the use of a communication means such as the Internet, a dedicated line or the like without going through the external memory device 283. Furthermore, the memory part 282 or the external memory device 283 is configured by a non-transitory computer-readable recording medium. Hereinafter, the memory part 282 and the external memory device 283 will be generally and simply referred to as “recording medium.” When the term “recording medium” is used herein, it may indicate a case of including only the memory part 282, a case of including only the external memory device 283, or a case of including both the memory part 282 and the external memory device 283. In addition, when the term “program” is used herein, it may indicate a case of including only a control program, a case of including only an application program, or a case of including both the control program and the application program.

### (2) Configuration of Process Module

Next, the configuration of the process chambers RC1 to RC8 of the respective process modules PM1a to PM1d will be described.

Each of the process modules PM1a to PM1d serves as a single-substrate-type substrate processing apparatus. As described above, each of the process modules PM1a to PM1d includes two process chambers (reactors) RC1 to RC8. The respective process chambers RC1 to RC8 are similarly configured in any of the process modules PM1a to PM1d.

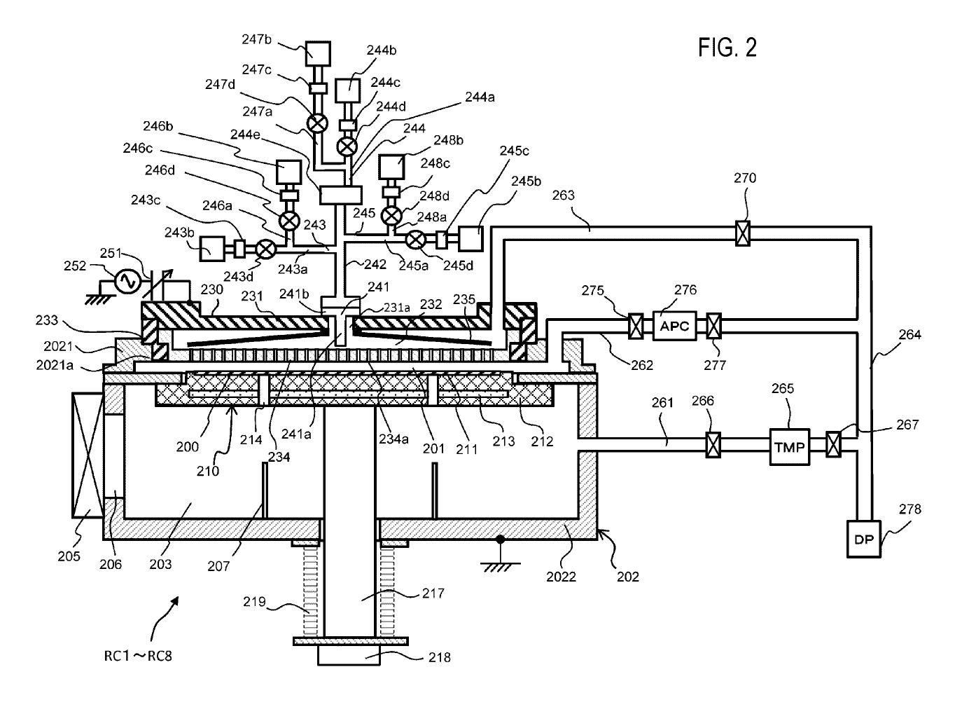

Descriptions will now be made on the specific configuration of each of the process chambers RC1 to RC8 of the respective process modules PM1a to PM1d. FIG. 2 is an explanatory view schematically illustrating a schematic configuration example of the process chamber of the substrate processing apparatus according to the first embodiment of the present disclosure.

### (Process Vessel)

As illustrated in FIG. 2, each of the process chambers RC1 to RC8 includes a process vessel 202. The process vessel 202 is formed of, for example, a flat sealed vessel having a circular cross section. The process vessel 202 includes an upper vessel 2021 made of, for example, a non-metallic material such as quartz, ceramics or the like, and a lower vessel 2022 made of, for example, a metallic material such as aluminum (Al), stainless steel (SUS) or the like. Within the process vessel 202, a process space (process room) 201 for processing a wafer 200 as a substrate such as a silicon wafer or the like is formed at the upper side (at the upper side of a substrate mounting table 212 which will be described later), and a transfer space 203 surrounded by the lower vessel 2022 is formed at the lower side.

A substrate loading/unloading gate 206 adjoining a gate valve 205 is installed on the side surface of the lower vessel 2022. The wafer 200 is loaded into the transfer space 203 through the substrate loading/unloading gate 206. A plurality of lift pins 207 is installed in the bottom portion of the lower vessel 2022. The lower vessel 2022 is kept at a ground potential.

### (Substrate Mounting Table)

A substrate support part (susceptor) 210 for supporting the wafer 100 is installed within the process space 201. The substrate support part 210 mainly includes a mounting surface 211 for mounting the wafer 200, a substrate mounting table 212 having the mounting surface 211, and a heater 213 as a heating part installed within the substrate mounting table 212. Through-holes 214, through which the lift pins 207 pass, are formed in the substrate mounting table 212 in the positions corresponding to the lift pins 207.

The substrate mounting table 212 is supported by a shaft 217. The shaft 217 penetrates the bottom portion of the process vessel 202. Furthermore, the shaft 217 is connected to an elevator mechanism 218 outside the process vessel 202. If the shaft 217 and the substrate mounting table 212 are moved up and down by operating the elevator mechanism 218, it is possible for the substrate mounting table 212 to move up and down the wafer 200 mounted on the mounting surface 211. The lower end portion of the shaft 217 is covered with a bellows 219, whereby the interior of the process space 201 is kept air-tight.

When transferring the wafer 200, the substrate mounting table 212 is moved down so that the mounting surface 211 is located in the position of the substrate loading/unloading gate 206 (the wafer transfer position). When processing the wafer 200, the wafer 200 is moved up to the processing position within the process space 201 (the wafer processing position). Specifically, when the substrate mounting table 212 is moved down to the wafer transfer position, the upper end portions of the lift pins 207 protrude from the upper surface of the mounting surface 211 so that the lift pins 207 support the wafer 200 from the lower side thereof. Furthermore, when the substrate mounting table 212 is moved up to the wafer processing position, the lift pins 207 retract from the upper surface of the mounting surface 211 so that the mounting surface 211 supports the wafer 200 from the lower side thereof. Since the lift pins 207 make direct contact with the wafer 200, the lift pins 207 may be made of, for example, quartz or alumina. In addition, elevator mechanisms may be installed in the lift pins 207 so as to move the lift pins 207.

### (Shower Head)

A shower head 230 as a gas diffusion mechanism is installed in the upper portion of the process space 201 (at the upstream side in the gas supply direction). The shower head 230 is inserted into, for example, a hole 2021a formed in the upper vessel 2021. The shower head 230 is fixed to the upper vessel 2021 through a hinge not shown and is configured to be opened using the hinge when performing maintenance.

A lid 231 of the shower head 230 is made of, for example, metal having electric conductivity and heat conductivity. A block 233 is installed between the lid 231 and the upper vessel 2021. The block 233 provides electric insulation and thermal insulation between the lid 231 and the upper vessel 2021.

A through-hole 231a, into which a gas supply pipe 241 as a first diffusion mechanism is inserted, is formed in the lid 231 of the shower head 230. The gas supply pipe 241 inserted into the through-hole 231a is configured to diffuse the gas supplied into a shower head buffer chamber 232 which is a space formed within the shower head 230. The gas supply pipe 241 includes a distal end portion 241a inserted into the shower head 230 and a flange 241b fixed to the lid 231. The distal end portion 241a is formed in, for example, a cylindrical columnar shape. Diffusion holes are formed on the side surface of the distal end portion 241a having the cylindrical columnar shape. The gas supplied from a gas supply part (supply system) which will be described later is supplied into the shower head buffer chamber 232 through the distal end portion 241a and the diffusion holes.

Furthermore, the shower head 230 includes a diffusion plate 234 as a second diffusion mechanism for diffusing the gas supplied from a gas supply part (supply system) which will be described later. The upstream side of the diffusion plate 234 is the shower head buffer chamber 232. The downstream side of the diffusion plate 234 is the process space 201. A plurality of through-holes 234a is formed in the diffusion plate 234. The diffusion plate 234 is disposed at the upper side of the mounting surface 211 so as to face the mounting surface 211. Thus, the shower head buffer chamber 232 communicates with the process space 201 through the through-holes 234a formed in the diffusion plate 234.

A gas guide 235 for forming a flow of the supplied gas is installed within the shower head buffer chamber 232. The gas guide 235 is formed in a conical shape so that the diameter thereof grows larger from a vertex, i.e., the through-hole 231a into which the gas supply pipe 241 is inserted, toward the diffusion plate 234. The gas guide 235 is formed so that the lower end portion thereof is positioned more outward than the through-holes 234a formed at the outermost side of the diffusion plate 234. That is to say, the shower head buffer chamber 232 accommodates the gas guide 235 for guiding the gas supplied from the upper side of the diffusion plate 234 toward the process space 201.

A matcher 251 and a high-frequency power source 252 are connected to the lid 231 of the shower head 230. By adjusting impedance with the matcher 251 and the high-frequency power source 252, plasma is generated within the shower head buffer chamber 232 and the process space 201.

Furthermore, the shower head 230 may contain a heater (not shown) as a heat source for heating the interior of the shower head buffer chamber 232 and the interior of the process space 201. The heater is configured to heat the interior of the shower head buffer chamber 232 at a temperature at which the gas supplied into the shower head buffer chamber 232 is not re-liquefied. For example, the heater is controlled so as to heat the interior of the shower head buffer chamber 232 at about 100 degrees C.

### (Gas Supply System)

A common gas supply pipe 242 is connected to the gas supply pipe 241 inserted into the through-hole 231a formed in the lid 231 of the shower head 230. The gas supply pipe 241 and the common gas supply pipe 242 are in communication with each other. The gas supplied from the common gas supply pipe 242 is supplied into the shower head 230 through the gas supply pipe 241 and the through-hole 231a.

A first gas supply pipe 243a, a second gas supply pipe 244a and a third gas supply pipe 245a are connected to the common gas supply pipe 242. Among them, the second gas supply pipe 244a is connected to the common gas supply pipe 242 via a remote plasma unit 244e.

A first-element-containing gas is mainly supplied from a first gas supply system 243 including the first gas supply pipe 243a. A second-element-containing gas is mainly supplied from a second gas supply system 244 including the second gas supply pipe 244a. When processing the wafer 200, an inert gas is mainly supplied from a third gas supply system 245 including the third gas supply pipe 245a. When cleaning the shower head 230 or the process space 201, a cleaning gas is mainly supplied from the third gas supply system 245 including the third gas supply pipe 245a.

### (First Gas Supply System)

A first gas supply source 243b, a mass flow controller (MFC) 243c, which is a flow rate controller (flow rate control part), and a valve 243d, which is an opening/closing valve, are installed in the first gas supply pipe 243a sequentially from the upstream side. A gas containing a first element (hereinafter referred to as “first-element-containing gas”) is supplied from the first gas supply source 243b into the shower head 230 via the MFC 243c, the valve 243d, the first gas supply pipe 243a and the common gas supply pipe 242.

The first-element-containing gas, which is one of the process gases, acts as a precursor gas. In this regard, the first element is, for example, titanium (Ti). That is to say, the first-element-containing gas is, for example, a titanium-containing gas. Furthermore, the first-element-containing gas may be one of a solid, a liquid and a gas under room temperature and atmospheric pressure. If the first-element-containing gas is a liquid under room temperature and atmospheric pressure, a vaporizer not shown may be installed between the first gas supply source 243b and the MFC 243c. Descriptions will be made herein under the assumption that the first-element-containing gas is a gas.

A downstream end of a first inert gas supply pipe 246a is connected to the first gas supply pipe 243a at the downstream side of the valve 243d. An inert gas supply source 246b, a mass flow controller (MFC) 246c, which is a flow rate controller (flow rate control part), and a valve 246d, which is an opening/closing valve, are installed in the first inert gas supply pipe 246a sequentially from the upstream side. An inert gas is supplied from the inert gas supply source 246b into the shower head 230 via the MFC 246c, the valve 246d, the first inert gas supply pipe 246a, the first gas supply pipe 243a and the common gas supply pipe 242.

In this regard, the inert gas acts as a carrier gas for the first-element-containing gas. A gas not reacting with the first element may be used as the inert gas. Specifically, for example, a nitrogen (N₂) gas may be used as the inert gas. As the inert gas, in addition to the N₂ gas, it may be possible to use, for example, a rare gas such as a helium (He) gas, a neon (Ne) gas, an argon (Ar) gas or the like.

A first gas supply system (also referred to as “titanium-containing-gas supply system”) 243 is mainly configured by the first gas supply pipe 243a, the MFC 243c and the valve 243d. Furthermore, a first inert gas supply system is mainly configured by the first inert gas supply pipe 246a, the MFC 246c and the valve 246d. The first gas supply system 243 may include the first gas supply source 243b and the first inert gas supply system. The first inert gas supply system may include the inert gas supply source 234b and the first gas supply pipe 243a. The first gas supply system 243 is configured to supply a precursor gas which is one of the process gases. Thus, the first gas supply system 243 corresponds to one of the process gas supply systems.

### (Second Gas Supply System)

A remote plasma unit 244e is installed at the downstream side of the second gas supply pipe 244a. A second gas supply source 244b, a mass flow controller (MFC) 244c, which is a flow rate controller (flow rate control part), and a valve 244d, which is an opening/closing valve, are installed in the second gas supply pipe 244a sequentially from the upstream side. A gas containing a second element (hereinafter referred to as “second-element-containing gas”) is supplied from the second gas supply source 244b into the shower head 230 via the MFC 244c, the valve 244d, the second gas supply pipe 244a, the remote plasma unit 244e and the common gas supply pipe 242. At this time, the second-element-containing gas is converted to a plasma state by the remote plasma unit 244e and is supplied onto the wafer 200.

The second-element-containing gas, which is one of the process gases, acts as a reaction gas or a modification gas. In this regard, the second-element-containing gas contains a second element differing from the first element. The second element is, for example, one of oxygen (O), nitrogen (N) and carbon (C). In the present embodiment, the second-element-containing gas is assumed to be, for example, a nitrogen-containing gas. Specifically, an ammonia (NH₃) gas is used as the nitrogen-containing gas.

A downstream end of a second inert gas supply pipe 247a is connected to the second gas supply pipe 244a at the downstream side of the valve 244d. An inert gas supply source 247b, a mass flow controller (MFC) 247c, which is a flow rate controller (flow rate control part), and a valve 247d, which is an opening/closing valve, are installed in the second inert gas supply pipe 247a sequentially from the upstream side. An inert gas is supplied from the inert gas supply source 247b into the shower head 230 via the MFC 247c, the valve 247d, the second inert gas supply pipe 247a, the second gas supply pipe 244a and the common gas supply pipe 242.

In this regard, the inert gas acts as a carrier gas or a dilution gas in a substrate processing process. Specifically, for example, a N₂ gas may be used as the inert gas. As the inert gas, in addition to the N₂ gas, it may be possible to use, for example, a rare gas such as a He gas, a Ne gas, an Ar gas or the like.

A second gas supply system (also referred to as “nitrogen-containing-gas supply system”) 244 is mainly configured by the second gas supply pipe 244a, the MFC 244c and the valve 244d. Furthermore, a second inert gas supply system is mainly configured by the second inert gas supply pipe 247a, the MFC 247c and the valve 247d. The second gas supply system 244 may include the second gas supply source 244b, the remote plasma unit 244e and the second inert gas supply system. The second inert gas supply system may include the inert gas supply source 247b, the second gas supply pipe 244a and the remote plasma unit 244e. The second gas supply system 244 is configured to supply a reaction gas or a modification gas which is one of the process gases. Thus, the second gas supply system 244 corresponds to one of process gas supply systems.

### (Third Gas Supply System)

A third gas supply source 245b, a mass flow controller (MFC) 245c, which is a flow rate controller (flow rate control part), and a valve 245d, which is an opening/closing valve, are installed in the third gas supply pipe 245a sequentially from the upstream side. An inert gas is supplied from the third gas supply source 245b into the shower head 230 via the MFC 245c, the valve 245d, the third gas supply pipe 245a and the common gas supply pipe 242.

In a substrate processing process, the inert gas supplied from the third gas supply source 245b acts as a purge gas which purges the gas remaining within the process vessel 202 or the shower head 230. In a cleaning process, the inert gas supplied from the third gas supply source 245b may act as a carrier gas for a cleaning gas or a dilution gas. For example, a N₂ gas may be used as the inert gas. As the inert gas, in addition to the N₂ gas, it may be possible to use, for example, a rare gas such as a He gas, a Ne gas, an Ar gas or the like.

A downstream end of a cleaning gas supply pipe 248a is connected to the third gas supply pipe 245a at the downstream side of the valve 245d. A cleaning gas supply source 248b, a mass flow controller (MFC) 248c, which is a flow rate controller (flow rate control part), and a valve 248d, which is an opening/closing valve, are installed in the cleaning gas supply pipe 248a sequentially from the upstream side. A cleaning gas is supplied from the cleaning gas supply source 248b into the shower head 230 via the MFC 248c, the valve 248d, the cleaning gas supply pipe 248a, the third gas supply pipe 245a and the common gas supply pipe 242.

In a cleaning process, the cleaning gas supplied from the cleaning gas supply source 248b acts as a cleaning gas which removes a byproduct or the like adhering to the shower head 230 or the process vessel 202. As the cleaning gas, it may be possible to use, for example, a nitrogen trifluoride (NF₃) gas. Furthermore, as the cleaning gas, in addition to the NF₃ gas, it may be possible to use, for example, a hydrogen fluoride (HF) gas, a chlorine trifluoride (ClF₃) gas, a fluorine (F₂) gas or a combination thereof.

A third gas supply system 245 is mainly configured by the third gas supply pipe 245a, the mass flow controller 245c and the valve 245d. Furthermore, a cleaning gas supply system is mainly configured by the cleaning gas supply pipe 248a, the mass flow controller 248c and the valve 248d. The third gas supply system 245 may include the third gas supply source 245b and the cleaning gas supply system. The cleaning gas supply system may include the cleaning gas supply source 248b and the third gas supply pipe 245a.

(Gas Exhaust system)

An exhaust system for exhausting the atmosphere of the process vessel 202 includes a plurality of exhaust pipes connected to the process vessel 202. Specifically, the exhaust system include an exhaust pipe (first exhaust pipe) 261 connected to the transfer space 203, an exhaust pipe (second exhaust pipe) 262 connected to the process space 201, and an exhaust pipe (third exhaust pipe) 263 connected to the shower head buffer chamber 232. An exhaust pipe (fourth exhaust pipe) 264 is connected to the downstream side of the respective exhaust pipes 261, 262 and 263.

The exhaust pipe 261 is connected to the side surface or the bottom surface of the transfer space 203. A turbo molecular pump (TMP) (hereinafter also referred to as “first vacuum pump”) 265 as a vacuum pump for realizing high vacuum or ultrahigh vacuum is installed in the exhaust pipe 261. Valves 266 and 267, which are opening/closing valves, are installed in the exhaust pipe 261 at the upstream side and the downstream side of the TMP 265.

The exhaust pipe 262 is connected to the lateral side of the process space 201. An auto pressure controller (APC) 276, which is a pressure controller for controlling the interior of the process space 201 at a predetermined pressure, is installed in the exhaust pipe 262. The APC 276 includes a valve body (not shown) capable of adjusting an opening degree. In response to the instructions transmitted from the controller 280, the APC 276 adjusts the conductance of the exhaust pipe 262. Valves 275 and 277, which are opening/closing valves, are installed in the exhaust pipe 262 at the upstream side and the downstream side of the APC 276.

The exhaust pipe 263 is connected to the lateral side or the upper side of the shower head buffer chamber 232. A valve 270, which is an opening/closing valve, is installed in the exhaust pipe 263.

A dry pump (DP) 278 is installed in the exhaust pipe 264. As illustrated in FIG. 2, the exhaust pipe 263, the exhaust pipe 262 and the exhaust pipe 261 are connected to the exhaust pipe 264 at the upstream side thereof. The DP 278 is installed at the downstream side of the exhaust pipe 264. The DP 278 is configured to exhaust the atmospheres of the shower head buffer chamber 232, the process space 201 and the transfer space 203 through the exhaust pipe 262, the exhaust pipe 263 and the exhaust pipe 261. When the TMP 265 is operated, the DP 278 serves as an auxiliary pump thereof. In other words, the TMP 265, which is a high-vacuum (ultrahigh-vacuum) pump, has difficulty in independently performing the exhaust to atmospheric pressure. Thus, the DP 278 is used as an auxiliary pump which performs the exhaust to atmospheric pressure.

### (3) Winding Form of Pipe

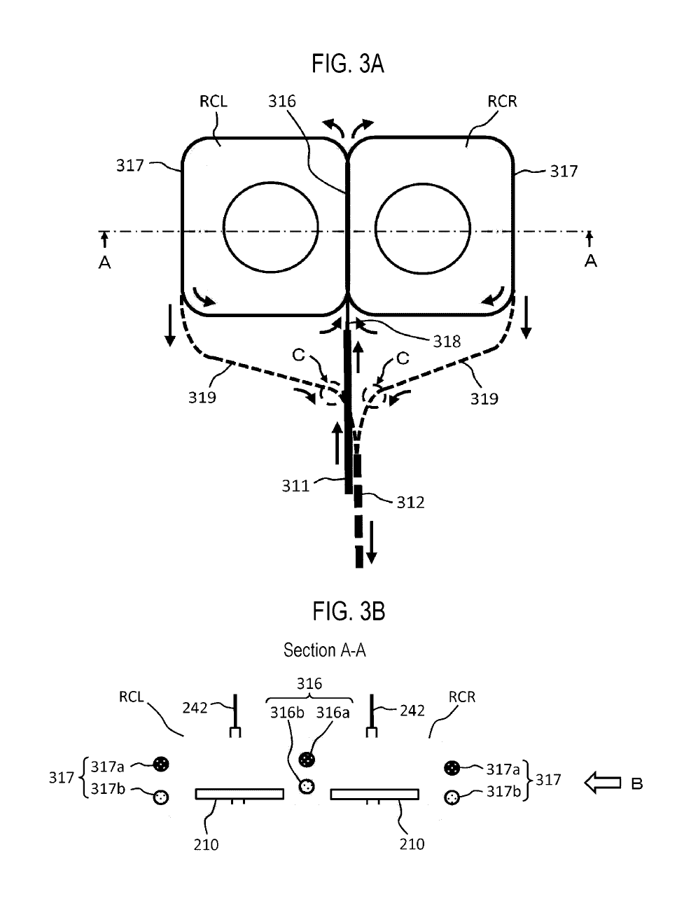

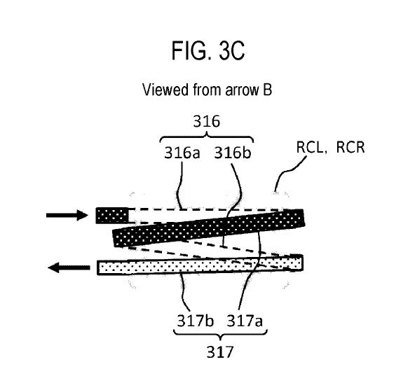

Next, descriptions will be made on the specific form of winding of the pipes 310a to 310d wound around the respective process modules PM1a to PM1d. FIGS. 3A to 3C are explanatory views schematically illustrating one example of a winding form of the pipe in the substrate processing apparatus according to the first embodiment.

As described above, each of the process modules PM1a to PM1d is configured to include a plurality of (e.g., two) process chambers (reactor) RC1 to RC8. In the example illustrated in FIG. 3A, each of the process modules PM1a to PM1d includes two process chambers RCL and RCR. The process chamber RCL corresponds to the process chambers RC1, RC3, RC5 and RC7 illustrated in FIG. 1. The process chamber RCR corresponds to the process chambers RC2, RC4, RC6 and RC8 illustrated in FIG. 1. The respective process chambers RCL and RCR are disposed adjacent to each other in a state in which the internal atmospheres thereof are isolated from each other.

The respective process chambers RCL and RCR have the same configuration (see, e.g., FIG. 2). A main wall member (namely the constituent member of the lower vessel 2022), which constitutes the sidewall for dividing the interior and exterior of each of the process chambers, is made of a metallic material such as aluminum, stainless steel or the like. A portion of each of the pipes 310a to 310d, through which the heat medium supplied from the temperature adjustment parts 320a to 320d flows, is wound around the sidewalls of the process chambers RCL and RCR. The term “wound” used herein means that a pipe portion is mounted to the process chambers RCL and RCR in a state in which the pipe portion is wound so as to surround the outer periphery side of the sidewalls of the process chambers RCL and RCR. Thus, in the respective process chambers RCL and RCR, heat exchange with the heat medium flowing through the wound pipe portion is performed through the sidewalls made of a metallic material having high heat conductivity.

The respective process chambers RCL and RCR are juxtaposed in an adjoining relationship with each other. Thus, the pipe portion wound around the respective process chambers RCL and RCR is configured to pass through a partition wall that isolates the respective process chambers RCL and RCR. That is to say, the sidewall of each of the process chambers RCL and RCR includes a partition wall disposed between the process chambers RCL and RCR and an outer wall exposed to the outer periphery side of the process chambers RCL and RCR. The pipe portion wound around each of the process chambers RCL and RCR includes a penetration pipe portion 316 as a penetration flow path portion extending through the partition wall disposed between the process chambers RCL and RCR and an outer periphery pipe portion 317 as an outer periphery flow path portion extending along the outer periphery side of the outer wall of each of the process chambers RCL and RCR.

As illustrated in FIG. 3C, the penetration pipe portion 316 and the outer periphery pipe portion 317 are spirally wound from the upper side of each of the process chambers RCL and RCR toward the lower side thereof. The penetration pipe portion 316 extends through the partition wall disposed between the respective process chambers RCL and RCR. Thus, the penetration pipe portion 316 is disposed so that the penetration pipe portion 316 can be shared by the respective process chambers RCL and RCR. On the other hand, the outer periphery pipe portion 317 extends along the outer periphery side of the outer wall of each of the process chambers RCL and RCR. Thus, the outer periphery pipe portion 317 is individually disposed in each of the process chambers RCL and RCR. Accordingly, as illustrated in FIGS. 3A and 3B, the penetration pipe portion 316 and the outer periphery pipe portion 317 are disposed symmetrically in the left-right direction about the partition wall existing between the process chambers RCL and RCR. Thus, as illustrated in FIGS. 3B and 3C, the penetration pipe portion 316 includes an upper-end-side penetration pipe portion 316a positioned at the upper side of the spiral shape and a lower-end-side penetration pipe portion 316b positioned at the lower side of the spiral shape. Furthermore, the outer periphery pipe portion 317 includes an upper-end-side outer periphery pipe portion 317a positioned at the upper side of the spiral shape and a lower-end-side outer periphery pipe portion 317b positioned at the lower side of the spiral shape. In the example of the drawings, a case is illustrated where the spiral shape is formed of two upper and lower end side stages. However, the present disclosure is not limited thereto. The spiral shape may be appropriately set depending on the size of the process chambers RCL and RCR, the pipe diameter or the like.

As illustrated in FIG. 3A, the upstream pipe portion 311 is connected to the upper-end-side penetration pipe portion 316a of the penetration pipe portion 316, which is positioned at the upper end side of the spiral shape, through an upstream side connection pipe portion 318 as an upstream side connection flow path portion. It is conceivable that the upstream side connection pipe portion 318 is installed independently of the upstream pipe portion 311 and the upper-end-side penetration pipe portion 316a. Alternatively, the upstream side connection pipe portion 318 may be installed integrally with the upstream pipe portion 311. With this configuration, the heat medium supplied from the temperature adjustment parts 320a to 320d flows into the upper-end-side penetration pipe portion 316a.

The upper-end-side penetration pipe portion 316a is bifurcated at the downstream side thereof and is connected to the upper-end-side outer periphery pipe portions 317a corresponding to the respective process chambers RCL and RCR. The upper-end-side outer periphery pipe portions 317a are merged and are connected to the lower-end-side penetration pipe portion 316b. The lower-end-side penetration pipe portion 316b is bifurcated at the downstream side thereof and is connected to the lower-end-side outer periphery pipe portions 317b corresponding to the respective process chambers RCL and RCR.

The lower-end-side outer periphery pipe portion 317b of the outer periphery pipe portion 317, which is positioned at the lower end side of the spiral shape, is connected to the downstream pipe portion 312 through a downstream side connection pipe portion 319 as a downstream side connection flow path portion. It is conceivable that the downstream side connection pipe portion 319 is installed independently of the downstream pipe portion 312 and the lower-end-side outer periphery pipe portion 317b. Alternatively, the downstream side connection pipe portion 319 may be installed integrally with the downstream pipe portion 312. With this configuration, the heat medium discharged from the lower-end-side outer periphery pipe portion 317b flows into the downstream pipe portion 312.

In this way, the upstream pipe portion 311 is connected to the upper-end-side penetration pipe portion 316a. The downstream pipe portion 312 is connected to the lower-end-side outer periphery pipe portion 317b. Thus, the upstream pipe portion 311 and the downstream pipe portion 312 are configured so that the installation heights thereof differ from each other.

The pipes 310a to 310d, each of which includes the upstream pipe portion 311, the upstream side connection pipe portion 318, the penetration pipe portion 316, the outer periphery pipe portion 317, the downstream side connection pipe portion 319 and the downstream pipe portion 312, are made of a metallic pipe material having high heat conductivity, such as aluminum, stainless steel or the like.

Even when the pipes 310a to 310d are made of a metallic pipe material, if the heat medium is allowed to continuously flow through the pipes 310a to 310d while keeping the flow velocity of the heat medium high, there is a possibility that the surface metal of the metallic pipe material is ionized and a corrosion action is generated. In particular, if there is a structural portion in which the heat medium tends to stay, a corrosion action may be more rapidly generated in the structural portion than in other pipe portions. The structural portion in which the heat medium tends to stay may refer to, for example, a curvilinear pipe portion (corner portion) having a small curvature radius, an angled portion or a T-like structural portion intersecting the direction of a mainstream of the heat medium and may refer to a structural portion with which the heat medium having a high pressure is highly likely to collide. It is desirable that the structural portion in which the heat medium tends to stay does not exist in the pipes 310a to 310d.

Thus, the pipe portion wound around the respective process chambers RCL and RCR is configured as described below. Specifically, the penetration pipe portion 316 is the input side of the heat medium and the outer periphery pipe portion 317 is the output side of the heat medium. A flow path shape symmetrical in the left-right direction is employed so that the energy loss generated when the heat medium flows from the input side to the output side becomes uniform at the respective sides of the process chambers RCL and RCR.

By employing the configuration in which the penetration pipe portion 316 is the input side of the heat medium and the outer periphery pipe portion 317 is the output side of the heat medium, it is possible to form the upstream side connection pipe portion 318 in a linear shape. Thus, there is no need to dispose a corner portion having a small curvature radius or an angled portion at least at the input side of the heat medium. The flow of the heat medium is stronger at the upstream side, which is the input side, than at the downstream side, which is the output side. Thus, if the pipe portion is formed in a linear shape at the input side, it is possible to avoid a situation that the structural portion in which the heat medium tends to stay exists at the upstream side where the flow of the heat medium is strong.

In the downstream side connection pipe portion 319, there is a need to dispose a corner portion (e.g., a portion indicated by arrow C in FIG. 3A) in order to connect the downstream side connection pipe portion 319 to the outer periphery pipe portion 317. However, the downstream side connection pipe portion 319 is positioned at the downstream side where the flow of the heat medium is weak. Thus, even if there is a need to dispose a corner portion in the downstream side connection pipe portion 319, it is possible to restrain the heat medium having a high pressure from colliding with the corner portion. That is to say, if the penetration pipe portion 316 is the input side of the heat medium and if the outer periphery pipe portion 317 is the output side of the heat medium, it is possible to make sure that the curvature radius of the upstream side connection pipe portion 318 becomes larger than the curvature radius of the downstream side connection pipe portion 319 (namely that the curvature of the upstream side connection pipe portion 318 becomes smaller than the curvature of the downstream side connection pipe portion 319). This makes it possible to suppress the existence of the structural portion where the heat medium tends to stay.

In contrast, if the outer periphery pipe portion 317 is the input side of the heat medium and if the penetration pipe portion 316 is the output side of the heat medium, it is highly likely that the heat medium stays in a corner portion (e.g., a portion indicated by arrow C in FIG. 3A). Thus, there is a possibility that a corrosion action is generated. In order to prevent the corrosion action, the distance (pipe length) between each of the process chambers RCL and RCR and the corner portion may be increased and the curvature radius of the corner portion may be made small (the curvature of the corner portion may be made large).

However, in this case, there is a need to sufficiently secure a pipe installation space. As a result, the footprint (the space occupied by the substrate processing apparatus) increases. In contrast, as described above, if the pipe portion wound around the respective process chambers RCL and RCR is configured so that the penetration pipe portion 316 becomes the input side of the heat medium and the outer periphery pipe portion 317 becomes the output side of the heat medium, the footprint does not increase. Accordingly, if there is a need to take the footprint into account, the pipe portion may be configured so that the penetration pipe portion 316 becomes the input side of the heat medium and the outer periphery pipe portion 317 becomes the output side of the heat medium.

### (4) Substrate Processing Process

Next, as one of semiconductor device manufacturing processes, a process of forming a thin film on the wafer 200 using the process chambers RCL and RCR configured as above will be described. In the following descriptions, the operations of the respective parts constituting the substrate processing apparatus are controlled by the controller 280.

Descriptions will be made herein on an example in which a titanium nitride (TiN) as a metal thin film is formed on the wafer 200 by using a TiCl₄ gas, which is obtained by vaporizing TiCl₄, as a first-element-containing gas (first process gas), using a NH₃ gas as a second-element-containing gas (second process gas), and alternately supplying the TiCl₄ gas and the NH₃ gas.

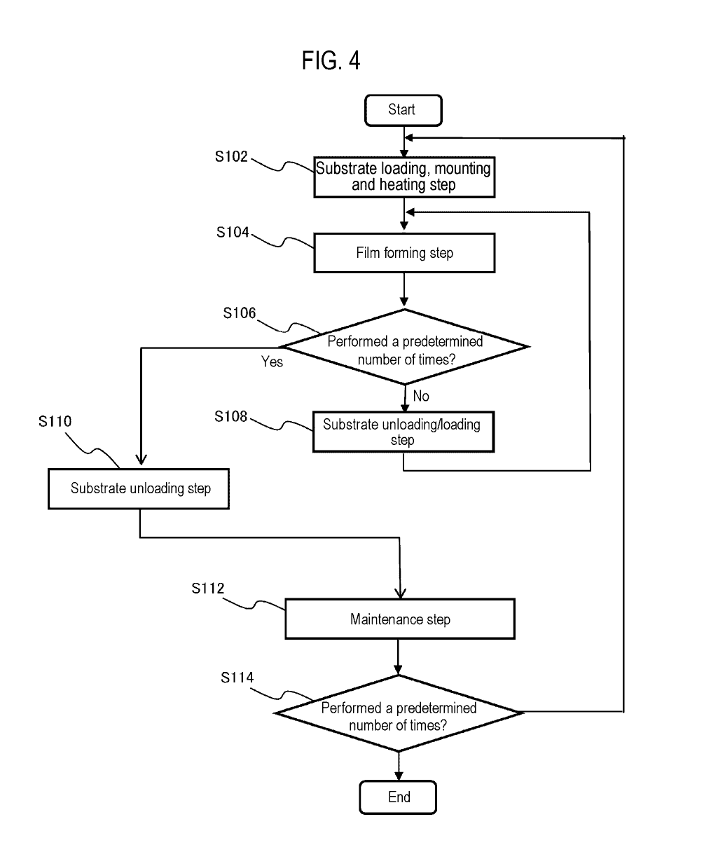

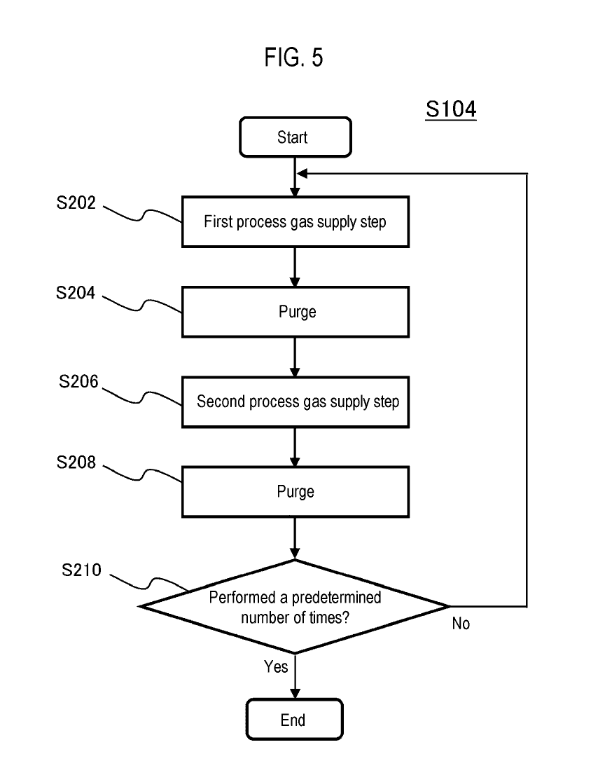

FIG. 4 is a flowchart illustrating an overview of a substrate processing process according to the present embodiment. FIG. 5 is a flowchart illustrating the details of a film forming process in the substrate processing process illustrated in FIG. 4.

### (Substrate Loading, Mounting and Heating Step: S102)

In each of the process chambers RCL and RCR, the substrate mounting table 212 is first moved down to the transfer position of the wafer 200, thereby allowing the lift pins 207 to penetrate the through-holes 214 of the substrate mounting table 212. As a result, the lift pins 207 protrude from the surface of the substrate mounting table 212 by a predetermined length. Subsequently, the gate valve 205 is opened to bring the transfer space 203 into communication with the vacuum transfer chamber 140. Then, the wafer 200 is loaded from the vacuum transfer chamber 140 into the transfer space 203 using the vacuum transfer robot 170 and is transferred onto the lift pins 207. Thus, the wafer 200 is horizontally supported on the lift pins 207 protruding from the surface of the substrate mounting table 212.

After the wafer 200 is loaded into the process vessel 202, the vacuum transfer robot 170 is retracted out of the process vessel 202 and the gate valve 205 is closed to seal the interior of the process vessel 202. Thereafter, the substrate mounting table 212 is moved upward so that the wafer 200 is mounted on the mounting surface 211 of the substrate mounting table 212. The substrate mounting table 212 is further moved upward so that the wafer 200 is moved up to the processing position (substrate processing position) within the aforementioned process space 201.

If the wafer 200 is loaded into the transfer space 203 and is then moved up to the processing position within the process space 201, the valves 266 and 267 are closed. Thus, the transfer space 203 and the TMP 265 are disconnected and the TMP 265 and the exhaust pipe 264 are disconnected. Thus, the exhaust of the transfer space 203 by the TMP 265 is completed. On the other hand, the valves 277 and 275 are opened to bring the process space 201 and the APC 276 into communication with each other and to bring the APC 276 and the DP 278 into communication with each other. The APC 276 adjusts the conductance of the exhaust pipe 262, thereby controlling the exhaust flow rate of the process space 201 exhausted by the DP 278 and keeping the process space 201 at a predetermined pressure (e.g., a high vacuum level of 10⁻⁵ to 10⁻¹ Pa).

In this process, a N₂ gas as an inert gas may be supplied from the inert gas supply system 245 into the process vessel 202 while exhausting the interior of the process vessel 202. In other words, while exhausting the interior of the process vessel 202 with the TMP 265 or the DP 278, at least the valve 245d of the third gas supply system may be opened to supply the N₂ gas into the process vessel 202. This makes it possible to restrain particles from adhering to the wafer 200.

When mounting the wafer 200 on the substrate mounting table 212, electric power is supplied to the heater 213 embedded within the substrate mounting table 212, thereby controlling the temperature of the surface of the wafer 200 so as to become a predetermined temperature. At this time, the temperature of the heater 213 is adjusted by controlling the state of power being supplied to the heater 213 based on the temperature information detected by a temperature sensor not shown.

As described above, at the substrate loading, mounting and heating step (S102), the internal pressure of the process space 201 is controlled to become a predetermined pressure and the surface temperature of the wafer 200 is controlled to become a predetermined temperature. The predetermined temperature and the predetermined pressure referred to herein are a temperature and a pressure at which, for example, a TiN film can be formed by an alternate supply method at a film forming step (S104) which will be described later. That is to say, the predetermined temperature and the predetermined pressure referred to herein are a temperature and a pressure at which a first-element-containing gas (precursor gas) supplied at a first process gas supply step (S202) is not autolyzed. Specifically, the predetermined temperature may be, for example, room temperature or more and 500 degrees C. or less, specifically, room temperature or more and 400 degrees C. or less. The predetermined pressure may be, for example, 50 to 5,000 Pa. The predetermined temperature and the predetermined pressure are maintained even at a film forming step (S104) which will be described below.

### (Film Forming Step: S104)

After the substrate loading, mounting and heating step (S102), a film forming step (S104) is performed. Hereinafter, the film forming step (S104) will be described in detail with reference to FIG. 5. The film forming step (S104) is a cyclic process in which different process gases are alternately supplied.

### (First Process Gas Supply Step: S202)

At the film forming step (S104), a first process gas supply step (S202) is first performed. When a TiCl₄ gas, which is a first-element-containing gas, is supplied as a first process gas at the first process gas supply step (S202), the valve 243d is opened and the MFC 243c is adjusted so that the flow rate of the TiCl₄ gas becomes a predetermined flow rate. Thus, the supply of the TiCl₄ gas into the process space 201 is started. The supply flow rate of the TiCl₄ gas is, for example, 100 sccm or more and 5,000 sccm or less. At this time, the valve 245d of the third gas supply system is opened and the N₂ gas is supplied from the third gas supply pipe 245a. The N₂ gas may be supplied from the first inert gas supply system. Prior to this step, the supply of the N₂ gas from the third gas supply pipe 245a may be started.

The TiCl₄ gas supplied into the process space 201 is supplied onto the wafer 200. As the TiCl₄ gas makes contact with the surface of the wafer 200, a titanium-containing layer as a “first-element-containing layer” is formed on the surface of the wafer 200.

The titanium-containing layer is formed at a predetermined thickness and a predetermined distribution depending on, for example, the internal pressure of the process vessel 202, the flow rate of the TiCl₄ gas, the temperature of the substrate support part (susceptor) 210, the time required in passing through the process space 201, and the like. A specific film may be formed in advance on the wafer 200. A specific pattern may be formed in advance on the wafer 200 or the specific film.

If a predetermined period of time elapses after the start of supply of the TiCl₄ gas, the valve 243d is closed to stop the supply of the TiCl₄ gas. The supply time period of the TiCl₄ gas is, for example, 2 to 20 seconds.

At the first process gas supply step (S202), the valves 275 and 277 are opened and the pressure of the process space 201 is controlled by the APC 276 so as to become a predetermined pressure. At the first process gas supply step (S202), all the valves of the exhaust system other than the valves 275 and 277 are kept closed.

### (Purge Step: S204)

After the supply of the TiCl₄ gas is stopped, the N₂ gas is supplied from the third gas supply pipe 245a to perform the purge of the shower head 230 and the process space 201. At this time, the valves 275 and 277 are opened and the pressure of the process space 201 is controlled by the APC 276 so as to become a predetermined pressure. All the valves of the exhaust system other than the valves 275 and 277 are kept closed. Thus, the TiCl₄ gas not bonded to the wafer 200 at the first process gas supply step (S202) is removed from the process space 201 through the exhaust pipe 262 by the DP 278. Subsequently, while maintaining the state in which the N₂ gas is supplied from the third gas supply pipe 245a, the valves 275 and 277 are closed and the valve 270 is opened. Other valves of the exhaust system are kept closed. In other words, the process space 201 and the APC 276 are disconnected and the APC 276 and the exhaust pipe 264 are disconnected. The pressure control performed by the APC 276 is stopped. The shower head buffer chamber 232 and the DP 278 are brought into communication with each other. Thus, the TiCl₄ gas remaining within the shower head 230 (the shower head buffer chamber 232) is exhausted from the shower head 230 through the exhaust pipe 263 by the DP 278.

At the purge step (S204), in order to remove the TiCl₄ gas remaining in the wafer 200, the process space 201 and the shower head buffer chamber 232, the exhaust efficiency is enhanced by supplying a large amount of purge gas.

After the purge of the shower head 230 is completed, the valves 277 and 275 are opened to resume the pressure control performed by the APC 276. The valve 270 is closed to disconnect the shower head 230 and the exhaust pipe 264. Other valves of the exhaust system are kept closed. Even in this case, the N₂ gas is continuously supplied from the third gas supply pipe 245a to continuously perform the purge of the shower head 230 and the process space 201. At the purge step (S204), the purge through the exhaust pipe 262 is performed before and after the purge through the exhaust pipe 263. However, only the purge through the exhaust pipe 263 may be performed. Alternatively, the purge through the exhaust pipe 263 and the purge through the exhaust pipe 262 may be simultaneously performed.

### (Second Process Gas Supply Step: S206)

After the purge of the shower head buffer chamber 232 and the process space 201 is completed, a second process gas supply step (S206) is performed. At the second process gas supply step (S206), the valve 244d is opened to start the supply of a NH₃ gas, i.e., a second-element-containing gas, as a second process gas into the process space 201 through the remote plasma unit 244e and the shower head 230. At this time, the MFC 244c is adjusted so that the flow rate of the NH₃ gas becomes a predetermined flow rate. The supply flow rate of the NH₃ gas is, for example, 1,000 to 10,000 sccm. Even at the second process gas supply step (S206), the valve 245d of the third gas supply system is opened and the N₂ gas is supplied from the third gas supply pipe 245a. By doing so, it is possible to prevent the NH₃ gas from entering the third gas supply system.

The NH₃ gas converted to a plasma state by the remote plasma unit 244e is supplied into the process space 201 through the shower head 230. The NH₃ gas thus supplied reacts with the titanium-containing layer formed on the wafer 200. The titanium-containing layer formed in advance is modified by the plasma of the NH₃ gas. Thus, for example, a TiN layer, which is a layer containing a titanium element and a nitrogen element, is formed on the wafer 200.

The TiN layer is formed at a predetermined thickness, a predetermined distribution and a predetermined infiltration depth of a nitrogen component into the titanium-containing layer, depending on, for example, the internal pressure of the process vessel 202, the flow rate of the NH₃ gas, the temperature of the substrate support part (susceptor) 210, the state of power supply to the remote plasma unit 244e, and the like.

If a predetermined time period elapses after the start of supply of the NH₃ gas, the valve 244d is closed to stop the supply of the NH₃ gas. The supply time period of the NH₃ gas is, for example, 2 to 20 seconds.

At the second process gas supply step (S206), similar to the first process gas supply step (S202), the valves 275 and 277 are opened and the pressure of the process space 201 is controlled by the APC 276 so as to become a predetermined pressure. Valves of the exhaust system other than the valves 275 and 277 are all kept closed.

### (Purge Step: S208)

After the supply of the NH₃ gas is stopped, a purge step (S208) similar to the aforementioned purge step (S204) is performed. The operations of the respective parts at the purge step (S208) are the same as those of the aforementioned purge step (S204). Thus, descriptions thereof will be omitted herein.

### (Determination Step: S210)

The first process gas supply step (S202), the purge step (S204), the second process gas supply step (S206) and the purge step (S208) are regarded as one cycle. The controller 280 determines whether the cycle has been performed a predetermined number of times (n cycles) (S210). If the cycle is performed a predetermined number of times, a TiN layer having a desired film thickness is formed on the wafer 200.

### (Determination Step: S106)

Turning back to the descriptions of FIG. 4, determination step (S106) is performed after the film forming step (S104) including the aforementioned steps (S202 to S210). At the determination step (S106), determination is made as to whether the film forming step (S104) has been performed a predetermined number of times. The term “a predetermined number of times” used herein refers to, for example, the number of times at which the film forming step (S104) is repeated such that a need of maintenance arises.

At the first process gas supply step (S202) of the aforementioned film forming step (S104), there may be a case where the TiCl₄ gas leaks to the transfer space 203 and enters the substrate loading/unloading gate 206. Similarly, at the second process gas supply step (S206), there may be a case where the NH₃ gas leaks to the transfer space 203 and enters the substrate loading/unloading gate 206. At the purge steps (S204 and S208), it is difficult to exhaust the atmosphere of the transfer space 203. Thus, if the TiCl₄ gas and the NH₃ gas enter the transfer space 203, the gases thus entered react with each other. Consequently, a film of a reaction byproduct or the like may be deposited on the wall surfaces of the interior of the transfer space 203 or the substrate loading/unloading gate 206. The film thus deposited may become particles. Accordingly, the interior of the process vessel 202 needs to be subjected to periodic maintenance.

Thus, if it is determined at the determination step (S106) that the number of performing times of the film forming step (S104) has not reached a predetermined number of times, a substrate unloading/loading step (S108) is started by determining that a need of maintenance for the interior of the process vessel 202 has not yet arisen. On the other hand, if it is determined at the determination step (S106) that the number of performing times of the film forming step (S104) has reached a predetermined number of times, a substrate unloading step (S110) is started by determining that a need of maintenance for the interior of the process vessel 202 has arisen.

### (Substrate Unloading/Loading Step: S108)

At the substrate unloading/loading step (S108), the processed wafer 200 is unloaded out of the process vessel 202 in an order opposite to the order of the aforementioned substrate loading, mounting and heating step (S102). Furthermore, the unprocessed wafer 200 on standby is loaded into the process vessel 202 in the same order as the order of the substrate loading, mounting and heating step (S102). Thereafter, the wafer 200 thus loaded is subjected to the film forming step (S104).

### (Substrate Unloading Step: S110)

At the substrate unloading step (S110), the processed wafer 200 is taken out so that the wafer 200 does not exist within the process vessel 202. Specifically, the processed wafer 200 is unloaded out of the process vessel 202 in an order opposite to the order of the aforementioned substrate loading, mounting and heating step (S102). Unlike the substrate unloading/loading step (S108), at the substrate unloading step (S110), a new wafer 200 on standby is not loaded into the process vessel 202.

### (Maintenance Step: S112)

After the substrate unloading step (S110) is completed, a maintenance step (S112) is started. At the maintenance step (S112), a cleaning process is performed with respect to the interior of the process vessel 202. Specifically, the valve 248d of the cleaning gas supply system is opened and the cleaning gas coming from the cleaning gas supply source 248b is supplied into the shower head 230 and the process vessel 202 through the third gas supply pipe 245a and the common gas supply pipe 242. The cleaning gas thus supplied is introduced into the shower head 230 and the process vessel 202 and is then exhausted through the first exhaust pipe 261, the second exhaust pipe 262 or the third exhaust pipe 263. Accordingly, at the maintenance step (S112), it is possible to perform a cleaning process in which the deposit (the reaction byproduct, etc.) mainly adhering to the interior of the shower head 230 and the interior of the process vessel 202 is removed using the flow of the cleaning gas. The maintenance step (S112) is completed after the cleaning process is performed for a predetermined time. The predetermined time is not particularly limited and may be appropriately set in advance.

### (Determination Step: S114)

A determination step (S114) is performed after the maintenance step (S112) is completed. At the determination step (S114), determination is made as to whether the aforementioned series of steps (S102 to S112) has been performed a predetermined number of times. The term “a predetermined number of times” used herein refers to, for example, the number of times corresponding to the pre-assumed number of wafers 200 (namely, the number of wafers 200 stored within the pod 111 mounted on the IO stage 110).

If it is determined that the number of times the respective steps (S102 to S112) are repeated has not reached a predetermined number of times, the aforementioned series of steps (S102 to S112) is performed again, starting from the substrate loading, mounting and heating step (S102). On the other hand, if it is determined that the number of times of the respective steps (S102 to S112) are repeated has reached a predetermined number of times, the aforementioned series of steps (S102 to S112) is completed by determining that the substrate processing process with respect to all the wafers 200 stored within the pod 111 mounted on the IO stage 110 has been finished.

### (5) Temperature Adjustment Process Using Temperature Adjustment System Part

Next, a temperature adjustment process performed with respect to the respective process chambers RC1 to RC8 by the temperature adjustment system part 20 at the aforementioned series of substrate processing steps will be described with reference to FIG. 1. In the following descriptions, the operations of the respective parts constituting the temperature adjustment system part 20 are controlled by the controller 280.

### (Supply of Heat Medium)

During the time when each of the process chambers RC1 to RC8 of the respective process modules PM1a to PM1d performs the aforementioned series of substrate processing steps (S102 to S114), the respective temperature adjustment parts 320a to 320d of the temperature adjustment system part 20 operate the pumps 324 to supply the heat medium into the pipes 310a to 310d. Thus, the respective process chambers RC1 to RC8 perform heat exchange with the heat medium, whereby the respective process chambers RC1 to RC8 are maintained at a predetermined temperature (e.g., about 50 degrees C.).

At this time, each of the sensors 315a to 315d installed in the upstream pipe portions 311 of the respective pipes 310a to 310d detects the state of the heat medium flowing through the pipes. The data detected by the respective sensors 315a to 315d are sent to the controller 280. Based on the data received from the respective sensors 315a to 315d, the controller 280 controls the respective temperature adjustment parts 320a to 320d. Specifically, the temperature adjustment part 320a is controlled based on the data detected by the sensor 315a. The temperature adjustment part 320b is controlled based on the data detected by the sensor 315b. In this way, the respective temperature adjustment parts 320a to 320d are controlled by the controller 280 based on the data detected by the corresponding sensors 315a to 315d. Based on the detection results of the respective sensors 315a to 315d, the respective temperature adjustment parts 320a to 320d independently control the pumps 324 so that the states of the heat medium supplied to the respective process modules PM1a to PM1d become uniform.

### (Sensor Detection)

As the sensors 315a to 315d for detecting the state of the heat medium, it may be possible to use, for example, sensors capable of measuring one of the pressure, flow rate and temperature of the heat medium or a combination thereof. Specifically, for example, the sensors 315a to 315d detect the temperature of the heat medium as the state of the heat medium. Furthermore, for example, the sensors 315a to 315d detect the pressure of the heat medium as the state of the heat medium and detect the leakage or non-leakage of the heat medium outside of the pipes, which may be generated due to the fluctuation of the pressure. Moreover, for example, the sensors 315a to 315d detect the flow rate of the heat medium as the state of the heat medium. In addition, for example, the sensors 315a to 315d detect the flow rate and temperature of the heat medium as the state of the heat medium. This makes it possible to find the heat capacity of the heat medium. In particular, it is known that the heat capacity can be uniquely found depending on the specific heat, flow rate and temperature of the heat medium. In other words, the heat capacity can be easily found by measuring the flow rate or the temperature. Accordingly, it is possible to easily grasp whether the heat medium supplied to the outer periphery pipe portion 317 maintains a desired heat capacity.

The respective sensors 315a to 315d installed in the respective pipes 310a to 310d are disposed at the same distance from the respective process modules PM1a to PM1d corresponding to the sensors 315a to 315d. For example, the distance (pipe length) between the sensor 315a installed in the upstream pipe portion 311 of the pipe 310a and the process module PM1a corresponding thereto is set to become substantially equal to the distance (pipe length) between the sensor 315b installed in the upstream pipe portion 311 of the pipe 310b and the process module PM1b corresponding thereto. By doing so, it is possible to make the detection conditions of the respective sensors 315a to 315d installed in the respective pipes 310a to 310d substantially uniform, when viewed from the respective process modules PM1a to PM1d.

### (Control of State of Heat Medium Based on Sensor Detection Result)

If the sensors 315a to 315d detect the state of the heat medium, the respective temperature adjustment parts 320a to 320d control the state of the heat medium in the below-described manner. For example, when the sensors 315a to 315d detect the temperature of the heat medium, if the detection results of the sensors 315a to 315d are lower than a predetermined temperature range, the corresponding temperature adjustment parts 320a to 320d heat the heat medium with the heating unit 322 so that the detection results fall within the predetermined temperature range. On the contrary, if the detection results of the sensors 315a to 315d are higher than the predetermined temperature range, the heat medium is cooled by the cooling unit 323. Furthermore, for example, when the sensors 315a to 315d detect the pressure of the heat medium, if the detection results of the sensors 315a to 315d fall outside a predetermined pressure range, the corresponding temperature adjustment parts 320a to 320d control the operations of the pumps 324 so that the pressure of the heat medium falls within the predetermined pressure range. Moreover, for example, when the sensors 315a to 315d detect the flow rate of the heat medium, if the detection results of the sensors 315a to 315d fall outside a predetermined flow rate range, the corresponding temperature adjustment parts 320a to 320d control the operations of the flow rate control parts 325 so that the flow rate of the heat medium falls within the predetermined flow rate range. In addition, for example, when the sensors 315a to 315d detect the temperature and flow rate of the heat medium, if the detection results of the sensors 315a to 315d fall outside a predetermined temperature range, the corresponding temperature adjustment parts 320a to 320d control the operations of the heating units 322 or the cooling units 323 so that the temperature of the heat medium falls within the predetermined temperature range. If the detection results of the sensors 315a to 315d fall outside a predetermined flow rate range, the corresponding temperature adjustment parts 320a to 320d control the operations of the flow rate control parts 325 so that the flow rate of the heat medium falls within the predetermined flow rate range.

As described above, the respective temperature adjustment parts 320a to 320d perform control based on the detection results of the respective sensors 315a to 315d so that the heat medium flowing through the respective pipes 310a to 310d is kept in a predetermined state. In other words, if the heat medium is not in a predetermined state, the respective temperature adjustment parts 320a to 320d control the state of the heat medium so that the predetermined state is recovered. Accordingly, the heat medium supplied to the respective process modules PM1a to PM1d by the respective temperature adjustment parts 320a to 320d is kept in the predetermined state.

Moreover, the respective temperature adjustment parts 320a to 320d perform the recovery control for the state of the heat medium independently of each other. In other words, the control content of one temperature adjustment part 320a is decided based on the detection result of the sensor 315a installed in a corresponding relationship with the temperature adjustment part 320a and is not affected by the control content of other temperature adjustment parts 320b to 320d. Thus, even when the pipe lengths of the respective pipes 310a to 310d are set differently in each of the process modules PM1a to PM1d for the reasons of installation environment such as, for example, a cleanliness within a clean room or the like, it is possible to make the states of the heat medium supplied to the respective process modules PM1a to PM1d substantially uniform, without being affected by the difference of the pipe lengths.

### (Process at Maintenance Step)

The maintenance step (S112) is included in the aforementioned series of substrate processing steps (S102 to S114). In the foregoing descriptions, there has been illustrated, by way of example, a case where the maintenance step (S112) is performed when the number of performing times of the film forming step (S104) reaches a predetermined number of times. However, the present disclosure is not necessarily limited thereto. For example, even before the film forming step (S104) is performed a predetermined number of times, when an error of a level that makes it necessary to perform maintenance is generated in the pipes 310a to 310d through which the heat medium flows, it may be possible to perform the maintenance step (S112). In addition, when there is a problem in the processing result of the wafer 200, it may be possible to appropriately perform the maintenance step (S112).

The maintenance step (S112) is performed in each of the process modules PM1a to PM1d. When performing the maintenance step (S112), the circulation of the heat medium is stopped by closing the valves 313 and 314 of the pipes 310a to 310d connected to the process modules PM1a to PM1d which become the targets of maintenance. However, with respect to the process modules PM1a to PM1d which do not become the targets of maintenance, the heat medium is continuously supplied by opening the valves 313 and 314. In other words, the temperature adjustment system part 20 includes the temperature adjustment parts 320a to 320d individually installed in a corresponding relationship with the respective process modules PM1a to PM1d. It is therefore possible to perform the maintenance step (S112) on the unit of the respective process modules PM1a to PM1d.

If the maintenance step (S112) is performed on the unit of the respective process modules PM1a to PM1d, even when the target of maintenance is one of the process modules PM1a to PM1d, it is not necessary to stop the supply of the heat medium to all the process modules PM1a to PM1d. Accordingly, it is possible to suppress significant reduction in the operation efficiency of the respective process module, which may occur when performing the maintenance step (S112).

Even when the maintenance step (S112) is performed on the unit of the respective process modules PM1a to PM1d, the respective temperature adjustment parts 320a to 320d perform the control of the state of the heat medium independently of each other. Thus, as for the state of the heat medium, the process modules PM1a to PM1d, which are the targets of maintenance, do not affect the process modules PM1a to PM1d, which are not the targets of maintenance. Specifically, the respective temperature adjustment parts 320a to 320d independently manage the heat medium supplied to the respective process modules PM1a to PM1d. Thus, even if the supply of the heat medium is stopped with respect to only the target of maintenance, it is possible to avoid a situation that a change in heat balance within the system is generated in response to the stop or resumption of the supply of the heat medium. In other words, there is no possibility that the fluctuation of the temperature of the heat medium supplied to the process modules PM1a to PM1d, which are not the targets of maintenance, is generated due to the stop or resumption of the supply of the heat medium. Thus, there is no need to postpone the start of a process until the fluctuation of the temperature of the heat medium is stabilized. It is therefore possible to suppress reduction of the operation efficiency of the respective process modules PM1a to PM1d.

As described above, the respective temperature adjustment parts 320a to 320d individually installed in a corresponding relationship with the respective process modules PM1a to PM1d perform the control of the state of the heat medium independently of each other. Thus, even when performing the maintenance step (S112), it is possible to shorten the downtime of the respective process modules PM1a to PM1d and to enhance the management efficiency of the apparatus as a whole.

### (6) Effect of the Present Embodiment

According to the present embodiment, one or more effects set forth below may be achieved.

(a) In the present embodiment, the temperature adjustment parts 320a to 320d are individually installed in a corresponding relationship with the process modules PM1a to PM1d. The respective temperature adjustment parts 320a to 320d perform the recovery control for the state of the heat medium independently of each other. Thus, according to the present embodiment, it is possible to realize maintenance on the unit of the respective process modules PM1a to PM1d and to suppress reduction of the operation efficiency of the respective process modules PM1a to PM1d, which may be attributable to the maintenance.

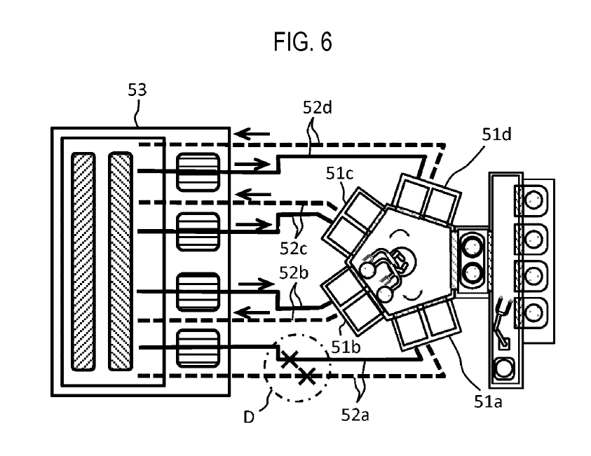

Descriptions will now be made on a comparative example of the present embodiment. FIG. 6 is an explanatory view schematically illustrating one example of the substrate processing apparatus according to a comparative example. Similar to the present embodiment described above, the substrate processing apparatus of the illustrated example includes a plurality of (e.g., four) process modules 51a to 51d. Pipes 52a to 52d are wound around the respective process modules 51a to 51d. One temperature adjustment unit 53 is connected to the respective pipes 52a to 52d. The temperature adjustment unit 53 collectively supplies a heat medium to the respective pipes 52a to 52d and allows the heat medium to circulate through the respective pipes 52a to 52d, thereby maintaining the process chambers (reactors) of the respective process modules 51a to 51d at a predetermined temperature (e.g., about 50 degrees C.). In the substrate processing apparatus configured as above, when performing maintenance, for the reasons of work environment, the supply of the heat medium to the pipes 52a to 52d wound around the process modules 51a to 51d is stopped (e.g., see arrow D in FIG. 6). However, since one temperature adjustment unit 53 collectively supplies the heat medium to the respective pipes 52a to 52d, even if the target of maintenance is one process module 51a, the influence of maintenance of one process module 51a may reach other process modules 51b to 51d which are not the targets of maintenance. That is to say, due to the influence of maintenance, there is a possibility that the operation efficiency of the respective process modules 51a to 51d is reduced.

In contrast, according to the present embodiment, the temperature adjustment parts 320a to 320d are individually installed in a corresponding relationship with the respective process modules PM1a to PM1d. The respective temperature adjustment parts 320a to 320d perform the recovery control for the state of the heat medium independently of each other. Thus, even when there is a need to perform maintenance with respect to one of the process modules PMla to PM1d, it is possible to suppress reduction of the operation efficiency of the respective process modules PM1a to PM1d. Moreover, since the respective temperature adjustment parts 320a to 320d perform the recovery control for the state of the heat medium independently of each other, it is possible to maintain the processing condition of the respective process modules PM1a to PM1d at a condition under which a specified quality is obtained. In other words, when the same process is performed in the respective process modules PM1a to PM1d in order to enhance the productivity, it is possible to keep the qualities of the respective wafers 200 processed by the respective process modules PM1a to PM1d constant.

(b) Furthermore, in the present embodiment, although the pipe lengths of the respective pipes 310a to 310d are set to become different in each of the process modules PM1a to PM1d, the respective temperature adjustment parts 320a to 320d perform the recovery control for the state of the heat medium independently of each other. Thus, according to the present embodiment, even if the pipe lengths of the respective pipes 310a to 310d differ from each other, it is possible to make the states of the heat medium supplied to the respective process modules PM1a to PM1d substantially uniform and to make the temperature adjustment states of the respective process modules PM1a to PM1d substantially uniform.

(c) Furthermore, in the present embodiment, as long as the sensors 315a to 315d installed in the respective pipes 310a to 310d detect the pressure or the flow rate of the heat medium, even if there is a change in the pressure or the flow rate of the heat medium, it is possible for the respective temperature adjustment parts 320a to 320d to perform the recovery control. Thus, according to the present embodiment, it is possible to enable the state of the pressure or the flow rate of the heat medium supplied to the respective process modules PM1a to PM1d to fall within a range in which no difference is generated in the film forming state.

(d) Furthermore, in the present embodiment, as long as the sensors 315a to 315d installed in the respective pipes 310a to 310d detect the temperature of the heat medium, even if there is a change in the temperature of the heat medium, it is possible for the respective temperature adjustment parts 320a to 320d to perform the recovery control. Thus, according to the present embodiment, it is possible to enable the state of the temperature of the heat medium supplied to the respective process modules PM1a to PM1d to fall within a range in which no difference is generated in the film forming state.

(e) Furthermore, in the present embodiment, the pipe lengths of the respective pipes 310a to 310d from the installation positions of the respective sensors 315a to 315d to the respective process modules PM1a to PM1d are set so that the loss amount of the state of the heat medium flowing through the pipes 310a to 310d falls within a predetermined range. Thus, according to the present embodiment, it is possible to enable the loss amount such as the pressure reduction, the flow rate reduction or the temperature reduction of the heat medium detected by the sensors 315a to 315d to fall within a predetermined range. This makes it possible to suppress a change in the state of the heat medium, which may be generated until the heat medium whose state is detected by each of the sensors 315a to 315d reaches each of the process modules PM1a to PM1d.

(f) Furthermore, in the present embodiment, the pipe lengths of the respective pipes 310a to 310d from the installation positions of the respective sensors 315a to 315d to the respective process modules PM1a to PM1d are set to become uniform in the respective pipes 310a to 310d. Thus, according to the present embodiment, it is possible to make the detection conditions of the respective sensors 315a to 315d installed in the respective pipes 310a to 310d substantially uniform. Even if a change in the state of the heat medium is generated until the heat medium whose state is detected by each of the sensors 315a to 315d reaches each of the process modules PM1a to PM1d, it is possible to restrain the change in the state from varying depending on the respective process modules PM1a to PM1d.

(g) Furthermore, in the present embodiment, the sensors 315a to 315d for detecting the state of the heat medium supplied to the process modules PM1a to PM1d are installed in the upstream pipe portions 311 of the respective pipes 310a to 310d. Thus, according to the present embodiment, it is possible to appropriately and reliably make the sensing conditions of the heat medium in the respective pipes 310a to 310d uniform. For example, if the sensors 315a to 315d are installed in the downstream pipe portions 312, a difference may be generated in the loss amount of the state (the temperature, etc.) of the heat medium in each of the process modules PM1a to PM1d. Thus, there is a possibility that a variation is generated in the sensing condition of the heat medium. In contrast, if the sensors 315a to 315d are installed in the upstream pipe portions 311, the heat medium is sensed before the heat medium reaches the respective process modules PM1a to PM1d. Thus, the sensing conditions are made uniform in an appropriate and reliable manner.

(h) Furthermore, in the present embodiment, each of the process modules PM1a to PM1d includes two process chambers (reactors) RCL and RCR. The upstream pipe portion 311 is connected to the upper-end-side penetration pipe portion 316a extending through between the respective process chambers RCL and RCR. The downstream pipe portion 312 is connected to the lower-end-side outer periphery pipe portion 317b extending along the outer periphery side of each of the process chambers RCL and RCR. Thus, according to the present embodiment, there is no need to dispose a corner portion having a small curvature radius or an angled portion at least at the input side of the heat medium. It is possible to form the pipes 310a to 310d in a linear shape. That is to say, it is possible to avoid a situation that the structural portion in which the heat medium tends to stay exists at the upstream side where the flow of the heat medium is strong. It is also possible to suppress generation of a corrosion action which may be caused by the ionization of metal of the pipe surface.

(i) Furthermore, in the present embodiment, the upstream side connection pipe portion 318 or the downstream side connection pipe portion 319 has a structure in which a corner portion or the like exists. For that reason, there is a possibility that a corrosion action is more easily generated in the upstream side connection pipe portion 318 or the downstream side connection pipe portion 319 than in other pipe portions. Thus, as described in the present embodiment, if the upstream side connection pipe portion 318 is installed independently of the upstream pipe portion 311 and the upper-end-side penetration pipe portion 316a and if the downstream side connection pipe portion 319 is installed independently of the downstream pipe portion 312 and the lower-end-side outer periphery pipe portion 317b, it is possible to replace the upstream side connection pipe portion 318 or the downstream side connection pipe portion 319 as a separate component and to more frequently replace the upstream side connection pipe portion 318 or the downstream side connection pipe portion 319 than other pipe portions. Accordingly, it is possible to easily and appropriately cope with the corrosion action which may be generated in the upstream side connection pipe portion 318 or the downstream side connection pipe portion 319.

(j) Furthermore, in the present embodiment, the upstream side connection pipe portion 318 or the downstream side connection pipe portion 319 may be integrally installed with the upstream pipe portion 311 or the downstream pipe portion 312. For example, if the upstream side connection pipe portion 318 or the downstream side connection pipe portion 319 is a separate component, there is a possibility that, due to the structural problem thereof, a step or the like is generated within the pipe at a connection point between the upstream side connection pipe portion 318 or the downstream side connection pipe portion 319 and the upstream pipe portion 311 or the downstream pipe portion 312. The step or the like generated at the connection point may become a portion with which the heat medium flowing through the pipe collides, namely a structural portion where the heat medium tends to stay. However, if the upstream pipe portion 311 or the downstream pipe portion 312 is integrally formed, a step or the like otherwise generated in a connection point does not exist. Thus, the heat medium does not stay. As a result, it is possible to reduce the maintenance frequency of the pipes 310a to 310d.

(k) Furthermore, in the present embodiment, the curvature radius of the upstream side connection pipe portion 318 is set to become larger than the curvature radius of the downstream side connection pipe portion 319. Thus, according to the present embodiment, even if a corner portion or the like exists in the upstream side connection pipe portion 318 or the downstream side connection pipe portion 319, it is possible to avoid a situation that the structural portion in which the heat medium tends to stay exists at the upstream side where the flow of the heat medium is strong. That is to say, the flow of the heat medium is stronger at the upstream side than at the downstream side. Thus, at the upstream side, it is possible to realize a structure in which the flow of the heat medium is dodged.

(l) Furthermore, in the present embodiment, the installation height of the upstream pipe portion 311 and the installation height of the downstream pipe portion 312 are set to differ from each other. Thus, according to the present embodiment, it is possible to form the flow paths of the heat medium leading to the respective process chambers RCL and RCR in a symmetrical shape in the left-right direction so that the penetration pipe portion 316 and the outer periphery pipe portion 317 have a spiral shape. That is to say, it is possible to enable the lengths of the pipes wound around the respective process chambers RCL and RCR to become equal to each other in the left-right direction. It is also possible to make the temperature adjustment conditions in the respective process chambers RCL and RCR uniform.

### Second Embodiment of the Present Disclosure

Next, descriptions will be made on a second embodiment of the present disclosure. The points differing from the aforementioned first embodiment will be mainly described herein and the same points as the first embodiment will not be described.

### (Apparatus Configuration)

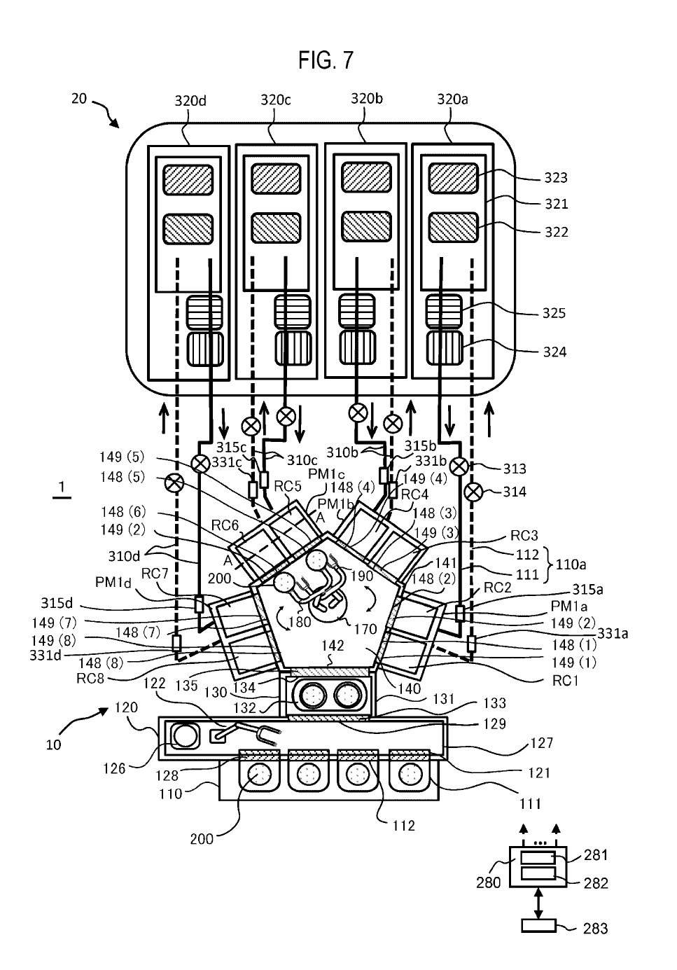

FIG. 7 is an explanatory view illustrating a schematic configuration example of a substrate processing apparatus according to a second embodiment. The substrate processing apparatus 1 of the illustrated example differs in configuration from the substrate processing apparatus of the first embodiment in that sensors 331a to 331d are installed in the downstream pipe portions 312 as well as the upstream pipe portions 311.

Similar to the sensors 315a to 315d installed in the upstream pipe portions 311, the sensors 331a to 331d detect the state of the heat medium flowing through the downstream pipe portions 312. That is to say, similar to the sensors 315a to 315d, the sensors 331a to 331d detect one of the pressure, flow rate and temperature of the heat medium or an appropriate combination thereof. The sensors 315a to 315d are configured to detect the state of the heat medium supplied from the respective temperature adjustment parts 320a to 320d to the respective process modules PM1a to PM1d. In contrast, the sensors 331a to 331d are configured to detect the state of the heat medium returned from the respective process modules PM1a to PM1d to the respective temperature adjustment parts 320a to 320d. The sensors 331a to 331d may be configured through the use of a well-known art. Detailed descriptions thereof will be omitted herein.

Similar to the sensors 315a to 315d, the sensors 331a to 331d installed in the respective pipes 310a to 310d are disposed at the same distance from the corresponding process modules PM1a to PM1d. For example, the distance (pipe length) between the sensor 331a installed in the downstream pipe portion 312 of the pipe 310a and the process module PM1a corresponding thereto is set to become substantially equal to the distance (pipe length) between the sensor 331b installed in the downstream pipe portion 312 of the pipe 310b and the process module PM1b corresponding thereto. By doing so, it is possible to make the detection conditions of the respective sensors 331a to 331d installed in the respective pipes 310a to 310d substantially uniform.

### (Control Process Based on Sensor Detection Result)

In the case where the sensors 331a to 331d are installed even in the downstream pipe portions 312 as in the present embodiment, the states of the heat medium are detected by the respective sensors 315a to 315d and 331a to 331d and the differences between the detection results of the respective sensors 315a to 315d and 331a to 331d are found. This makes it possible to determine the presence or absence of trouble of the heat medium between the sensors 315a to 315d and 331a to 331d.

Specifically, the state of the heat medium flowing through each of the pipes is detected by the sensor 315a installed in the upstream pipe portion 311 of one pipe 310a and the sensor 331a installed in the downstream pipe portion 312 of the pipe 310a. Then, a difference between the respective detection results is found. Determination is made as to whether the difference exceeds a predetermined permissible loss range. As a result, if the difference exceeds the permissible loss range, it is determined that leakage or clogging of the heat medium is possibly generated by a corrosion action in the pipe portion between the upstream pipe portion 311 and the downstream pipe portion 312. In other words, the possibility that the circulation of the heat medium is not normally performed in the respective pipes 310a to 310d is recognized based on the detection results of the respective sensors 315a to 315d and 331a to 331d. This recognition result may be notified and outputted to a maintenance worker, for example, as alarm information which indicates that there is a need to perform maintenance.

### Effect of the Present Embodiment

According to the present embodiment, in addition to the effects of the first embodiment described above, the effect set forth below may be achieved.

(m) In the present embodiment, in addition to the sensors (upstream sensors) 315a to 315d installed in the upstream pipe portion 311, the sensors (downstream sensors) 331a to 331d installed in the downstream pipe portion 312 are provided. Thus, according to the present embodiment, the possibility that the circulation of the heat medium is not normally performed can be recognized based on the detection results of the respective sensors 315a to 315d and 331a to 331d.

### Third Embodiment of the Present Disclosure

Next, descriptions will be made on a third embodiment of the present disclosure. The points differing from the aforementioned first embodiment will be mainly described herein and the same points as the first embodiment will not be described.

### (Apparatus Configuration)

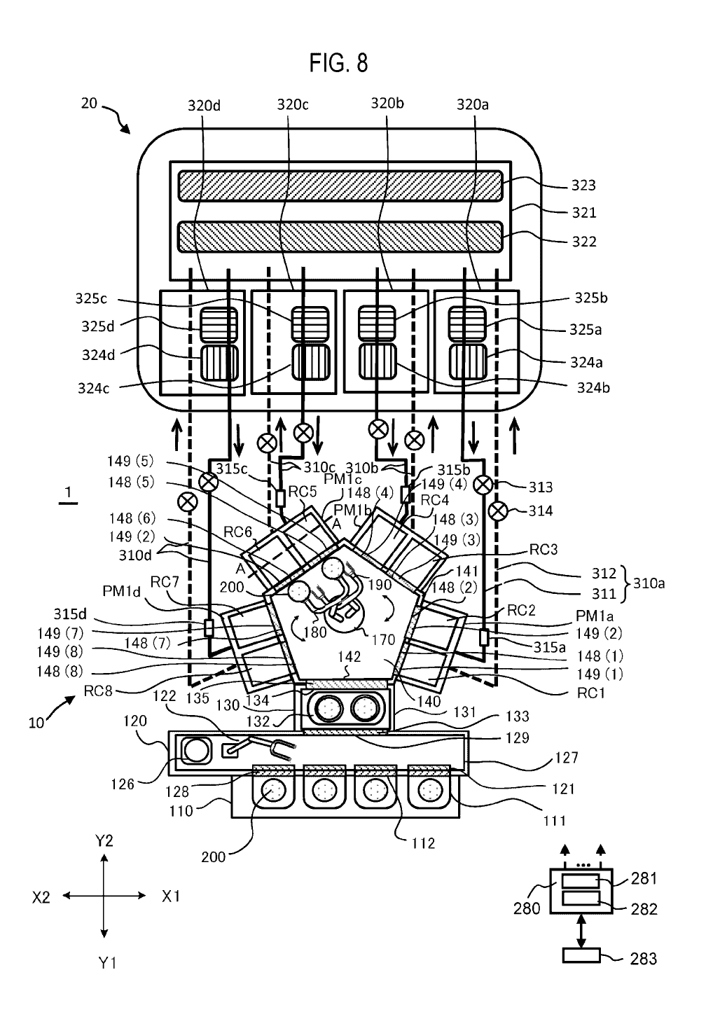

FIG. 8 is an explanatory view illustrating a schematic configuration example of a substrate processing apparatus according to a third embodiment. The substrate processing apparatus 1 of the illustrated example differs from the substrate processing apparatuses of the first and second embodiments in terms of the configuration of the temperature adjustment system part 20. Specifically, in the first and second embodiments, the respective temperature adjustment parts 320a to 320d are individually provided with the circulation tanks 321. However, in the substrate processing apparatus 1 of the illustrated example, one circulation tank 321 is shared by the respective temperature adjustment parts 320a to 320d.

The respective temperature adjustment parts 320a to 320d are individually provided with pumps 321a to 324d and flow rate control parts 325a to 325d. In other words, the pump 324a and the flow rate control part 325a are installed in the temperature adjustment part 320a. The pump 324b and the flow rate control part 325b are installed in the temperature adjustment part 320b. The pump 324c and the flow rate control part 325c are installed in the temperature adjustment part 320c. The pump 324d and the flow rate control part 325d are installed in the temperature adjustment part 320d.

### (Control Process Based on Sensor Detection Result)

In the substrate processing apparatus 1 configured as above, the temperature adjustment system part 20 is controlled by the controller 280 in the following manner.

For example, when the pressure of the heat medium is detected by the sensors 315a to 315d, if the detection results of the sensors 315a to 315d fall outside a predetermined pressure range, the corresponding temperature adjustment parts 320a to 320d individually control the operations of the pumps 324a to 324d so that the pressure of the heat medium falls within the predetermined pressure range. Accordingly, for example, if the detection result of the sensor 315a falls outside the predetermined pressure range, the temperature adjustment part 320a corresponding thereto controls the operation of the pump 324a. Therefore, the influence does not extend to other temperature adjustment parts 320b to 320d.

In addition, for example, when the flow rate of the heat medium is detected by the sensors 315a to 315d, if the detection results of the sensors 315a to 315d fall outside a predetermined flow rate range, the corresponding temperature adjustment parts 320a to 320d individually control the operations of the flow rate control parts 325a to 325d so that the flow rate of the heat medium falls within the predetermined flow rate range. Accordingly, for example, if the detection result of the sensor 315a falls outside the predetermined flow rate range, the temperature adjustment part 320a corresponding thereto controls the operation of the flow rate control part 325a. Therefore, the influence does not extend to other flow rate control parts 325b to 325d.

That is to say, in the present embodiment, even if the circulation tank 321 is shared by the respective temperature adjustment parts 320a to 320d, it is possible for the respective temperature adjustment parts 320a to 320d to independently perform the recovery control for the state of the heat medium.

### Effect of the Present Embodiment

According to the present embodiment, in addition to the effects of the first embodiment described above, the effect set forth below may be achieved.

(n) In the present embodiment, one circulation tank 321 is used in common. It is therefore possible to stably control the temperature of the heat medium and to control the heat capacity by merely opening or closing the valves 313 and 314. Thus, it is possible to make the temperatures of the outer peripheries of the respective process modules PM1a to PM1d uniform through the use of a simple configuration.

Furthermore, in the present embodiment, similar to the first embodiment, the sensors 315a to 315d are installed in the upstream pipe portions 311. However, the present disclosure is not limited thereto. Sensors 331a to 331d may also be installed in the downstream pipe portions 312.

### Other Embodiments

While the first, second and third embodiments of the present disclosure have been specifically described above, the present disclosure is not limited to the aforementioned respective embodiments but may be differently modified without departing from the spirit thereof.

For example, in the aforementioned respective embodiments, there has been illustrated, by way of example, a case where the flow paths, through which the heat medium flows, are the pipes 310a to 310d which are made of a metallic pipe material. However, the present disclosure is not limited thereto. In other words, the flow paths, through which the heat medium flows, are not limited to the ones which are formed of pipes, as long as the flow paths are installed in the respective process modules PM1a to PM1d. For example, the flow paths may be the ones formed in a hole shape or a groove shape within a metallic block material. Specifically, for example, one or more hole-shaped or groove-shaped flow paths, through which the heat medium flows, may be formed in the metallic block material. The metallic block material may be mounted in the vicinity of the wall surface of each of the process modules PM1a to PM1d. The heat medium may be allowed to flow through the metallic block material.

Furthermore, for example, in the aforementioned respective embodiments, there has been illustrated, by way of example, a case where each of the process modules PM1a to PM1d includes two process chambers RCL and RCR disposed adjacent to each other. However, the present disclosure is not limited thereto. In other words, each of the process modules PM1a to PM1d may include one process chamber or three or more process chambers.

Furthermore, for example, in the aforementioned respective embodiments, there has been illustrated, by way of example, a case where, in the film forming process performed by the substrate processing apparatus, the TiN film is formed on the wafer 200 by using the TiCl₄ gas as the first-element-containing gas (first process gas), using the NH₃ gas as the second-element-containing gas (second process gas) and alternately supplying the TiCl₄ gas and the NH₃ gas. However, the present disclosure is not limited thereto. In other words, the process gases used in the film forming process are not limited to the TiCl₄ gas and the NH₃ gas. Other kinds of thin films may be formed using other kinds of gases. Moreover, the present disclosure may be applied to a case where three or more kinds of process gases are used, as long as the film forming process is performed by alternately supplying the process gases. Specifically, the first element may not be Ti but may be, for example, a variety of elements such as Si, Zr, Hf or the like. In addition, the second element may not be N but may be, for example, O or the like.

Furthermore, for example, in the aforementioned respective embodiments, there has been illustrated, by way of example, a case where the process performed by the substrate processing apparatus is the film forming process. However, the present disclosure is not limited thereto. In other words, the present disclosure may be applied to film forming processes other than the film forming process illustrated in the aforementioned respective embodiments. The specific content of the film forming process does not matter. The present disclosure may be applied not only to the film forming process but also to other substrate processing processes such as an annealing process, a diffusion process, an oxidation process, a nitriding process, a lithography process and the like. Furthermore, the present disclosure may be applied to other substrate processing apparatuses such as, for example, an annealing apparatus, an etching apparatus, an oxidation apparatus, a nitriding apparatus, an exposure apparatus, a coating apparatus, a drying apparatus, a heating apparatus, a plasma-used processing apparatus and the like. Furthermore, these apparatuses may be used in combination. Moreover, some of the components of one embodiment may be replaced by the components of another embodiment. The components of one embodiment may be added to the components of another embodiment. In addition, other components may be added to the respective embodiments and some of the components of the respective embodiments may be deleted or replaced by other components.

According to the present disclosure in some embodiments, it is possible to, even when there is provided a plurality of process modules, keep the substrate processing condition of the respective process modules at a condition under which a specified quality is obtained.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
process chambers configured to process substrates;
a plurality of process modules each including a plurality of juxtaposed process chambers;
a plurality of heat medium flow paths respectively installed in the process modules; and
a plurality of temperature adjustment parts individually installed in a corresponding relationship with the process modules and configured to allow a heat medium, which adjusts a temperature of the process modules, to flow through the flow paths installed in the process modules,
wherein each of the flow paths includes:
an upstream flow path portion positioned at an upstream side of each of the process modules;
a downstream flow path portion positioned at a downstream side of each of the process modules;
a penetration flow path portion connected to the upstream flow path portion and configured to extend through between the juxtaposed process chambers of each of the process modules; and
an outer periphery flow path portion connected to the downstream flow path portion and configured to extend along an outer periphery of each of the process modules.

2. The apparatus of claim 1, wherein sensors configured to detect a state of the heat medium flowing through the flow paths are installed in the flow paths, and
the temperature adjustment parts are configured to, based on detection results of the sensors, control the heat medium flowing through the flow paths in a predetermined state.

3. The apparatus of claim 2, wherein the temperature adjustment parts are collectively installed in a spaced-apart relationship with the process modules, and
the flow paths are configured to individually interconnect the process modules and the temperature adjustment parts corresponding to the process modules and are configured so that the lengths of the flow paths vary depending on each the process modules.

4. The apparatus of claim 2, wherein the sensors have a function of detecting a pressure or a flow rate of the heat medium flowing through the flow paths, and
the temperature adjustment parts have a function of controlling the pressure or the flow rate of the heat medium flowing through the flow paths.

5. The apparatus of claim 4, wherein the sensors have a function of detecting a temperature of the heat medium flowing through the flow paths, and
the temperature adjustment parts have a function of controlling the temperature of the heat medium flowing through the flow paths.

6. The apparatus of claim 4, wherein the lengths of the flow paths from installation positions of the sensors to the process modules are set so that a loss amount of the state of the heat medium flowing through the flow paths falls within a predetermined range.

7. The apparatus of claim 4, wherein the lengths of the flow paths from installation positions of the sensors to the process modules are set so as to become uniform with respect to the process modules.

8. The apparatus of claim 2, wherein the sensors have a function of detecting a temperature of the heat medium flowing through the flow paths, and
the temperature adjustment parts have a function of controlling the temperature of the heat medium flowing through the flow paths.

9. The apparatus of claim 8, wherein the lengths of the flow paths from installation positions of the sensors to the process modules are set so that a loss amount of the state of the heat medium flowing through the flow paths falls within a predetermined range.

10. The apparatus of claim 2, wherein the lengths of the flow paths from installation positions of the sensors to the process modules are set so that a loss amount of the state of the heat medium flowing through the flow paths falls within a predetermined range.

11. The apparatus of claim 10, wherein the lengths of the flow paths from installation positions of the sensors to the process modules are set so as to become uniform with respect to the process modules.

12. The apparatus of claim 2, wherein each of the flow paths includes:
an upstream side connection flow path portion configured to interconnect the upstream flow path portion and the penetration flow path portion and installed independently of the upstream flow path portion and the penetration flow path portion; and
a downstream side connection flow path portion configured to interconnect the outer periphery flow path portion and the downstream flow path portion and installed independently of the outer periphery flow path portion and the downstream flow path portion.

13. The apparatus of claim 2, wherein the sensors include upstream sensors installed in the upstream flow path portions of the flow paths and downstream sensors installed in the downstream flow path portions of the flow paths.

14. The apparatus of claim 1, wherein the temperature adjustment parts are collectively installed in a spaced-apart relationship with the process modules, and
the flow paths are configured to individually interconnect the process modules and the temperature adjustment parts corresponding to the process modules and are configured so that the lengths of the flow paths vary depending on each the process modules.

15. The apparatus of claim 2, wherein the lengths of the flow paths from installation positions of the sensors to the process modules are set so as to become uniform with respect to the process modules.

16. The apparatus of claim 1, wherein each of the flow paths includes:
an upstream side connection flow path portion configured to interconnect the upstream flow path portion and the penetration flow path portion and installed independently of the upstream flow path portion and the penetration flow path portion; and
a downstream side connection flow path portion configured to interconnect the outer periphery flow path portion and the downstream flow path portion and installed independently of the outer periphery flow path portion and the downstream flow path portion.

17. The apparatus of claim 16, wherein each of the flow paths is configured so that a curvature radius of the upstream side connection flow path portion becomes larger than a curvature radius of the downstream side connection flow path portion.

18. The apparatus of claim 1, wherein each of the flow paths is configured so that an installation height of the upstream flow path portion and an installation height of the downstream flow path portion differ from each other.

19. A substrate processing apparatus, comprising:
process chambers configured to process substrates;
a plurality of process modules each including a plurality of juxtaposed process chambers;
a plurality of heat medium flow paths respectively installed in the process modules; and
a temperature adjustment part configured to allow a heat medium, which adjusts a temperature of the process modules, to flow through the flow paths installed in the process modules,
wherein each of the flow paths includes:
an upstream flow path portion positioned at an upstream side of each of the process modules;
a downstream flow path portion positioned at a downstream side of each of the process modules;
a penetration flow path portion connected to the upstream flow path portion and configured to extend through between the juxtaposed process chambers of each of the process modules; and
an outer periphery flow path portion connected to the downstream flow path portion and configured to extend along an outer periphery of each of the process modules.
